(19) United States
(12) Patent Application Publication
(10) Pub. No.: US 2025/0299030 A1
(43) Pub. Date: Sep. 25, 2025

(54) HYBRID BRAIN-ORGANOID-SEMICONDUCTOR COMPUTING SYSTEMS AND METHODS

(71) Applicant: The Trustees of Columbia University in The City of New York, New York, NY (US)

(72) Inventors: KENNETH SHEPARD, Ossining, NY (US); KENNETH KOSIK, Santa Barbara, CA (US)

(21) Appl. No.: 18/787,478

(22) Filed: Jul. 29, 2024

Related U.S. Application Data
(60) Provisional application No. 63/529,241, filed on Jul. 27, 2023.

(51) Int. Cl. G06N 3/06; G06N 3/063; H01L 25/065; H10D 80/30; H10D 84/01; H10D 84/85

(52) U.S. Cl. CPC G06N 3/061; G06N 3/063; H01L 25/0657; H10D 80/30; H10D 84/0165; H10D 84/85

(57) ABSTRACT

A brain-organoid complementary metal-oxide semiconductor (CMOS) processor and an associated method can be provided. For example, the CMOS structure can be a CMOS processor, which can be a co-processor. In addition or alternatively, the CMOS processor can include at least one culture which can comprise at least one brain organoid, and at least one CMOS device configured to interface with the at least one brain organoid. The CMOS device(s) can be configured to stimulate and record information from the brain organoid(s).

### CROSS REFERENCE TO RELATED APPLICATION(S)

This application relates to and claims the benefit of priority from U.S. Provisional Patent Application No. 63/529,241, filed on Jul. 27, 2023, the entire disclosure of which is incorporated herein by reference.

### FIELD OF THE DISCLOSURE

The present disclosure relates to semiconductor systems and methods, and more particularly to, e.g., hybrid brain-organoid-semiconductor computing systems and methods.

### BACKGROUND INFORMATION

Training of current artificial intelligence (AI) systems based on artificial neural networks (ANNs) implemented in complementary metal-oxide semiconductor (CMOS) electronics is not scalable both from memory and energy perspectives. As AI models become more complex, the energy to train these models is growing extensively. For example, GPT-4 required ˜30 GW-h of power to train, equivalent to that used by 2,500 homes in one year. If current trends continue, this will reach 3000 GW-h in just a few years (which is equal to the entire electric energy output of the United States).

Neuromorphic computing. Currently, the most aggressive efforts to address this challenge are in the development of a new generation of CMOS neuromorphic spiking neural network (SNN) processors. These include analog processors such as HICANN (see, e.g. Ref. 1) and NeuroGrid (see, e.g. Ref. 2), and digital ones, such as SpiNNaker (see, e.g. Ref. 3) and IBM's TrueNorth (see, e.g. Ref. 4). The most advanced semiconductor SNNs are the Intel Loihi (see, e.g. Ref. 5) and Loihi 2 (see, e.g. Ref. 6) designs. Loihi, in particular, provides support for on-chip learning with a microcode-programmable learning engine. The way in which these states are updated is determined by a learning rule. SNNs try to duplicate some of the ways in which the brain works, including its fine-grain parallelism and event-driven operation, but arguably come up short in matching the function and energy-efficiency of the brain.

Current comparisons of the operation of the brain to artificial neural networks—whether they be feedforward or concurrent—are superficial at best, and generally not effective. For example, back-propagation of errors used in the training of neural networks does not characterize the operation of in vivo neural circuitry. The human brain carries out computation through complex spatiotemporal dynamics, allowing the brain to process analog signals with a commendable power efficiency, i.e., the overall power consumption of the brain is around 20 Watts while providing power-efficient in-memory computing. The power efficiency of the brain relies on its core computational unit—the synapse—which, compared to a computer, paradoxically transmits information slowly and likely lacks fidelity.

Heterogeneous integration of CMOS with brain organoid. This results from the fact that the technology palette of the brain is fundamentally different than CMOS and that computing would be advanced significantly if processors could be made from a combination of solid-state and biological elements. We will use human brain organoids (see, e.g., Ref. 7) derived from induced pluripotent stem cells (iPSC) as this biological element with cellular, anatomical, and physiological resemblance to the brain. Human brain organoids bring the complexity of brain structures to biological systems that can be engineered and cultured around semiconductor components. Coupled to high-resolution electrophysiological CMOS interfaces, computing can be performed both biologically and electrically.

Recent Technological advances can make biological-CMOS systems possible. Advances in the growth of human brain organoids provide new biomaterials with the complexity of in vivo neural systems. Complementary advances in CMOS technologies that record and stimulate brain activity today enable recording and stimulating from tens of thousands of neurons with the spatiotemporal resolution necessary to probe the dynamics of organoid systems. Most recently, many advances in silico systems are upscaled by massive increases in memory and energy-intensive training from use data. However, scaling such approaches to deep learning may have already reached its limit, as it is believed that further advances would need a far deeper understanding of information processing in the brain and direct application of biological technologies in computation.

Unique characteristics of the biological palette. While it is possible to produce fully analog dynamical systems in CMOS or other solid-state systems, biological technologies can offer various features that may not be easily replicated in solid-state systems. Such technologies can be as follows:
Lower voltage operation than semiconductor systems, which should generally operate at 5 kT/q because of their reliance on transport over a barrier to modulate electrical conduction. Ion channels, on the other hand, generally rely on mechanical conformational changes and are not limited by barrier transport.
Sodium ion pumps, which are understood to be the dominant consumers of energy in the brain, charge membrane capacitances adiabatically; that is, such sodium ion pumps move charge across the actual potential across the membrane rather than source charge from a fixed (high) potential, as done in CMOS circuits.
The brain supports massive three-dimensional interconnection networks, significantly more extensive that would ever likely be possible in solid-state systems.
Dynamic generation of interconnections is widely employed in biological neural systems, rather than the far more expensive maintenance of synaptic weights. This can offer considerable energy savings compared to existing CMOS instantiations.

Thus, it may be beneficial to provide exemplary hybrid brain-organoid-semiconductor computing systems and methods, which can overcome at least some of the deficiencies described herein above.

### SUMMARY OF EXEMPLARY EMBODIMENTS

The following is intended to be a brief summary of the exemplary embodiments of the present disclosure, and is not intended to limit the scope of the exemplary embodiments of the present disclosure.

According to certain exemplary embodiments of the present disclosure, it is possible to provide AI processors that have both biological and semiconductor components, and which can take advantage of the complexity of function possible with neural systems at very low energy cost. For example, a comparison can be performed on CMOS-organoid-based recurrent neural network (RNN) computing with what can be achieved with the latest neuromorphic all-CMOS SNN processors. In particular, it is possible to compare the energy needed to train these systems so as to achieve, e.g., at least 100× improvement in Joules/accuracy for representative AI benchmarks such as MNIST (see, e.g., Ref. 8) and ImageNet (see, e.g., Ref. 9).

According to exemplary embodiments of the present disclosure, a brain-organoid complementary metal-oxide semiconductor (CMOS) processor and method can be provided. For example, the CMOS processor can be a co-processor. In addition or alternatively, the CMOS processor can include at least one culture which can comprise at least one brain organoid, and at least one CMOS device configured to interface with the at least one brain organoid. The CMOS device(s) can be configured to stimulate and record information from the brain organoid(s).

For example, it is possible to electro-physiologically interface or optically interface the at least one CMOS device with the at least one brain organoid. The CMOS device(s) can perform at least one operation or at least one computation to interface with the at least one brain organoid. Such exemplary operation(s) can include a performance of (i) encoding and decoding spikes from the brain organoid, and (ii) input or output layer training.

In yet another exemplary embodiment of the present disclosure, the CMOS device(s) can include one or more wireless interfaces. The brain organoid(s) can be configured to operate as a reservoir in a reservoir computing model. Further or alternatively, the brain organoid(s) can have learning structure and/or a long-term memory which can be utilized in a computing model. In another exemplary embodiment, the CMOS device(S) can be thinned and/or can have or more holes etched therethrough.

According still another exemplary embodiment of the present disclosure, the CMOS devices can be a plurality of CMOS devices. For example, at least two of the CMOS devices can be mounted in a back-to-back configuration with respect to one another. In addition or alternatively, the CMOS device(s) can include at least one reservoir computing model. In addition, the CMOS device(s) can include at least one feedback back loop connected to the brain organoid(s).

According to yet further exemplary embodiments of the present disclosure, the CMOS device(s) can include a plurality of CMOS devices which can be provided in a three-dimensional configuration. The CMOS device(s) can include a plurality of CMOS devices which can be provided in a stacked configuration. It is also possible to provide at least one interface which can facilitate a wireless connection, whereas the interface(s) can be coupled to the CMOS device(s).

These and other objects, features, and advantages of the exemplary embodiments of the present disclosure will become apparent upon reading the following detailed description of the exemplary embodiments of the present disclosure, when taken in conjunction with the appended claims.

### BRIEF DESCRIPTION OF THE DRAWINGS

Further objects, features and advantages of the present disclosure will become apparent from the following detailed description taken in conjunction with the accompanying Figures showing illustrative embodiments of the present disclosure, in which:

FIG. 1A is a set of illustrations of an exemplary model for reservoir computing as applied to the organoid as a reservoir, according to exemplary embodiments of the present disclosure;

FIG. 1B is a set of illustrations of another exemplary model for reservoir computing as applied to the organoid as a reservoir, according to further exemplary embodiments of the present disclosure;

FIG. 2 is a set of illustrations of an exemplary design of a culture well containing a wireless CMOS MEA, according to exemplary embodiments of the present disclosure;

FIG. 3A is a top view of an exemplary BISC1 chip implant that has an implanted device incorporates a post-processed array of TiN electrodes on the chip surface, with an aggressive substrate thinning gives the chip mechanical flexibility;

FIG. 3B is an illustration of thinned chips released from at 200-mm wafer, showing wafer-scale manufacturing;

FIG. 3C is an image of a mechanical flexibility of BISC1 implant;

FIG. 3D is an exemplary schematic of implant electronics;

FIG. 4 is an illustration of an exemplary structure of a brain organoid relative to full brains and simple neuronal cultures, according to exemplary embodiments of the present disclosure;

FIG. 5A is a signal graph providing a multi-unit activity recorded on an example BISC channel with 10-second trace showing cleanly isolatable neuronal firing from multiple neurons in MUA band (300 Hz-5 kHz);

FIG. 5B is a signal graph with an instantaneous firing rate of the two highlighted units (Gaussian convolved);

FIG. 5C is a signal graph providing Mean±SD waveforms (i) and all waveforms (ii and iii) for the highlighted units;

FIG. 6 is a set of images providing a model-based image reconstruction, whereas the top row shows the images presented to the monkey, and the bottom row shows images reconstructed from the BISC1 recorded data using the inverted digital-twin model;

FIG. 7 is an exemplary flow of an exemplary organoid culture procedure on the BISC2 16,384-channel BISC2 design, whereas the actual honeycomb is 10× denser than the rendering therein, in accordance with the exemplary embodiments of the present disclosure;

FIG. 8A is top view of four-well with perfusion of an exemplary fluidic setup for culturing organoids on suspended BISC2 chips with relay station station antenna, in accordance with the exemplary embodiments of the present disclosure;

FIG. 8B is a perspective view of the exemplary BISC2 antenna board design with four antennas, upon which the plate is positioned for the wireless interface, in accordance with the exemplary embodiments of the present disclosure

FIG. 8C is a side view of the perfusion of FIG. 8a, in accordance with the exemplary embodiments of the present disclosure;

FIG. 9A is am exemplary Four-bit memory design of of exemplary training sets for the organoid-CMOS processor, in accordance with the exemplary embodiments of the present disclosure;

FIG. 9B is an exemplary illustration of a MNIST characterization dataset; and

FIG. 9C are exemplary illustration of MNIST “1” being converted into 28 pulse sequences, in accordance with the exemplary embodiments of the present disclosure.

Throughout the drawings, the same reference numerals and characters, unless otherwise stated, are used to denote like features, elements, components or portions of the illustrated embodiments. Moreover, while the present disclosure will now be described in detail with reference to the figures, it is done so in connection with the illustrative embodiments and is not limited by the particular embodiments illustrated in the figures and the appended claims.

### DETAILED DESCRIPTION OF EXEMPLARY EMBODIMENTS

According to various exemplary embodiments of the present disclosure, it is possible to provide an exemplary computing model that can solve benchmark AI tasks, and is consistent with a system integrating both biological and semiconductor components. ANNs can generally be applied to deep-learning approaches, which use feedback error propagation, commonly known as backpropagation, in their training algorithms. This is a supervised learning approach that facilitates the network to adjust its weights in order to reduce the difference between the predicted output and the actual output for a given input. As indicated herein, deep learning approaches have at-best a superficial relationship to how the brain actually operates.

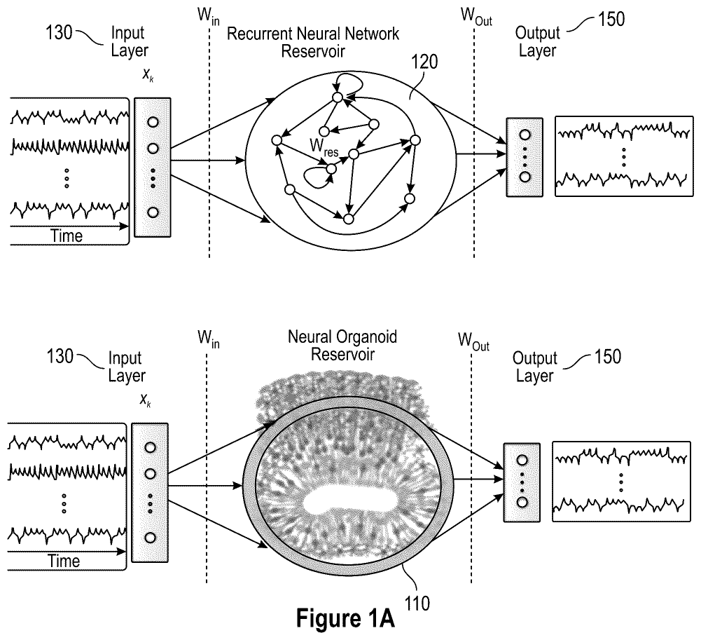

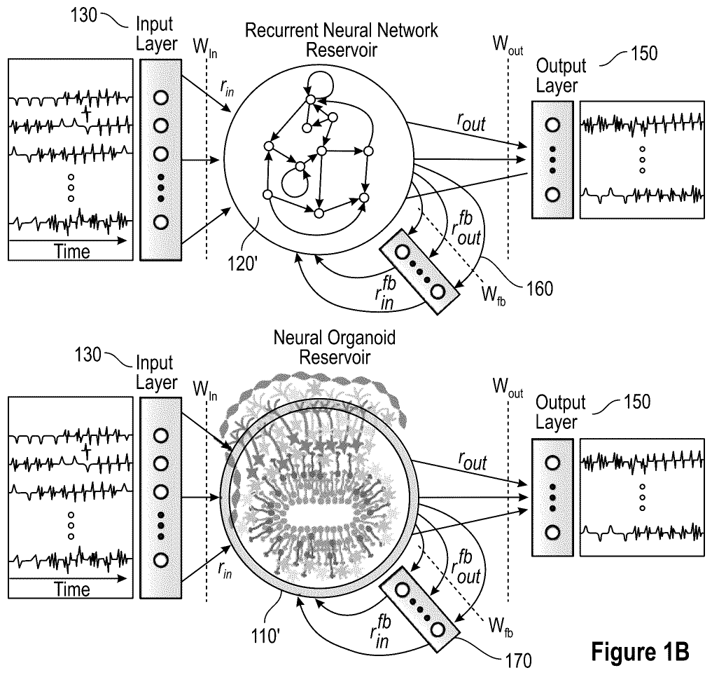

To address this and other issues, reservoir computing (RC) configurations can be utilized which facilitates the brain organoid to function as a high-dimensional reservoir without the need to engineer its structure or function, as shown in FIGS. 1A and 1B. According to the exemplary embodiments of the present disclosure, the use of RC configurations can be utilized which can include a feedback which can be a part of supervised learning.

RC in the context of CMOS-organoid computing is based on treating the organoid as an RNN (see, e.g., Ref. 11), a partially unstable dynamical system onto which input stimuli can be projected into high dimensions. Outputs can be determined through linear classification. In ANNs, RNNs differ from the more common feedforward neural networks in having topologies that includes cycles. (See, e.g., Ref. 12). These cycles provide the RNN self-sustaining temporal dynamics, as is observed in organoids. When driven by input signals, RNNs can have internal states that remember input history, giving them the dynamical memory needed to retain temporal context.

RNN ANN architectures for RC have taken the form of liquid-state machines (LSMs) (see, e.g., Ref. 13) and echo-state networks (ESNs) (see, e.g., Ref. 14). In these systems, in lieu of gradient-descent RNN training, the RNN is left unchanged during training with the network excited by the input signal. An output signal is generated from a linear combination of selected signals in the RNN, which is trained against the target response with the training data set (see, e.g., Ref. 11). The most common approach for this training is ridge regression. It is this classical read-out approach that has characterized the first attempt to use organoids as a reservoir (see, e.g., Ref. 10), where only the readout was trained. The problem with these classical read-out approaches was that they largely ignore the (sometimes) chaotic dynamics of the reservoir.

More recent RC models for ANNs have adopted on-line learning techniques (see, e.g., Ref. 15) giving feedback to the reservoir to control chaotic dynamics, the most influential of which has been the first-order reduced and controlled error (FORCE) (see, e.g., Ref. 16) algorithm. According to certain exemplary embodiments of the present disclosure, the exemplary model is generalized to incorporate feedback, as shown in FIG. 1B. In the most commonly used implementation of FORCE, feedback is provided from the output with a fixed and random weight back to controlling all the synapses in the RNN 120′. Prior attempts to implement something close to this with neuronal cultures, in which blanket control of all neurons was provided by glutamate uncaging optically over the entire culture, yielded mixed results (see, e.g., Ref. 17).

For the exemplary CMOS-organoid processors according to the exemplary embodiments of the present disclosure, it is possible to instead employ a variant of FORCE, described herein in further detail, as shown in FIG. 1B. For example, feedback is provided with trainable linear weights, which are trained together with the weights determining the outputs. In this case, choices must be made for four groups of connections into the organoid—the inputs, outputs, outputs for the feedback layer, and inputs to the feedback layer. As described in further detail herein, the initial selection of these connections can be made based on the analysis of a model of the organoid, which can be referred herein to as a “digital twin” which takes the form of an RNN or transformer model. Supervised learning in the organoid provided by this feedback can facilitate the number of electrodes needed for each of the four groups of connections into the organoid to be reduced over time as described in further detail herein. In this exemplary case, the organoid can be modified into a more general RNN model as as these supervised learning approaches are provided. Training can also facilitate the structure of the organoid to be guided during its development with stimulation affecting the final network architecture. The exemplary hardware can continuously stimulate and record during organoid growth and development. The high volumes of data afforded by this continuous recording can be important to the modelling efforts.

To that end, according to the exemplary embodiments of the present disclosure, the organoid can be provided that can function initially as a very high-dimensional, nonlinear dynamically RNN reservoir (as shown in FIGS. 1A and 1B). Feedback to the organoid can provide a form of supervised learning that is, initially, independent of changes in the properties of the reservoir itself but, over time, takes advantage of the ability of the reservoir to adapt to this feedback.

### Fully Wireless, Mesh-Based Active CMOS Multi-Electrode Array (MEAs)

The exemplary hardware (e.g., at the scale of 16,384 channels) can facilitate a minimal disturbance to the organoid during growth and development and provide for continuous recording and simulation of multiple organoids within a multi-well plate. The mesh structure can minimize or otherwise reduce the number of connections into the organoids while facilitating the diffusion of oxygen and nutrients. Fabricating this mesh directly into the CMOS electronics can provide, e.g., the maximum density of function. Wireless operation can facilitate these chips to be stacked in three dimensions to allow even more innervation of the CMOS with the organoid.

Low-Latency, Energy-Efficient Interfaces into the Organoid

Beneficial approaches to interface to single-unit activity (SUA) in the organoid can be provided both with biphasic stimulation and real-time spike-sorted outputs. Activity-based compression can be provided in the CMOS design and “light-weight” interfaces reviewed that can be implemented entire in the CMOS layer with a reduced or a minimal energy overhead.

### Complete “Digital Twin” Models of the Organoid

Based on the deep-learning models of cortical circuits (see, e.g., 18-22), it is possible to provide such “digital twin” predictive models of the organoid. These can be important for the following purposes. First, such exemplary models can provide deeper understanding of organoid structure and function similarly to how these models have been used in the cortex. Second, these models can facilitate a most appropriate initialization of the FORCE-based RC model employing the organoid, providing, e.g., an improved selection of inputs and outputs to the organoid based on its (untrained) structure. The exemplary use of both RNNs and transformer-based models for is described below for this purpose.

### FORCE-Based RC Computing Model

For example, a FORCE-based RC computing model according to the exemplary embodiments of the present disclosure can be provided that can have embedded within it the capability to incorporate supervised learning from the organoid itself. This can be accomplished with, e.g., a “distillation” process that increasingly drives the organoid to require fewer connections to the outside world to accomplish a given task. Provided below are the exemplary objects of the exemplary embodiments of the present disclosure described herein

Exemplary Object 1. Integration of Organoids onto Wireless, Mesh-Based CMOS Multielectrode Arrays (MEAs)

It is beneficial to provide BISC2, i.e., a mesh-based active CMOS MEA, building rely heavily on the existing BISC1 hardware, a wireless 65k-channel brain-computer interface (BCI) device. This exemplary hardware allows organoids to be cultured directly on top of the interface chips, improving quality, scale, and longevity of the recording and stimulating interfaces.

To that end, it is possible to utilize planar CMOS MEAs that facilitate a recording from up to, e.g., 1024 electrodes simultaneous and stimulation from up to, e.g., 32 channels. The limited number of channels, particularly for stimulation, can significantly limit the amount of data that can be collected. Because simply placing an organoid on the MEA can result in a relatively limited interfacial area (see, e.g. Ref. 10), slicing the organoid into ˜500-μm-thick slices before placing on the MEA (see, e.g., Ref. 7) was previously relied upon. This, however, can creates damage and many connections within the organoid can be lost in the process of slicing. Recording times are limited in these slices and contamination often results from the significant handling required.

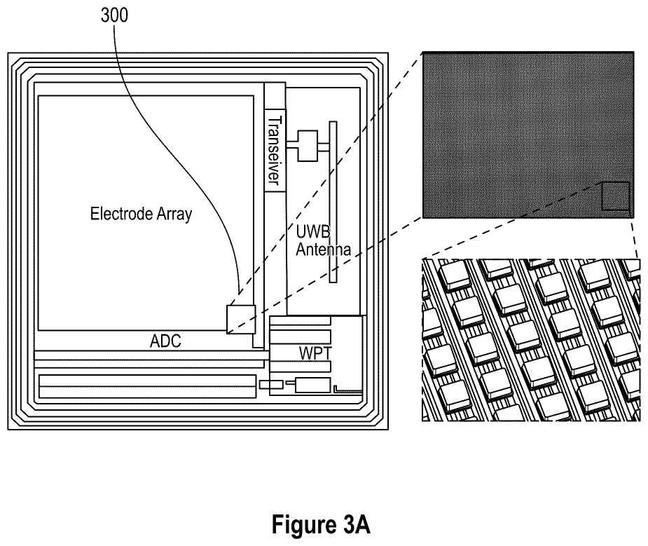

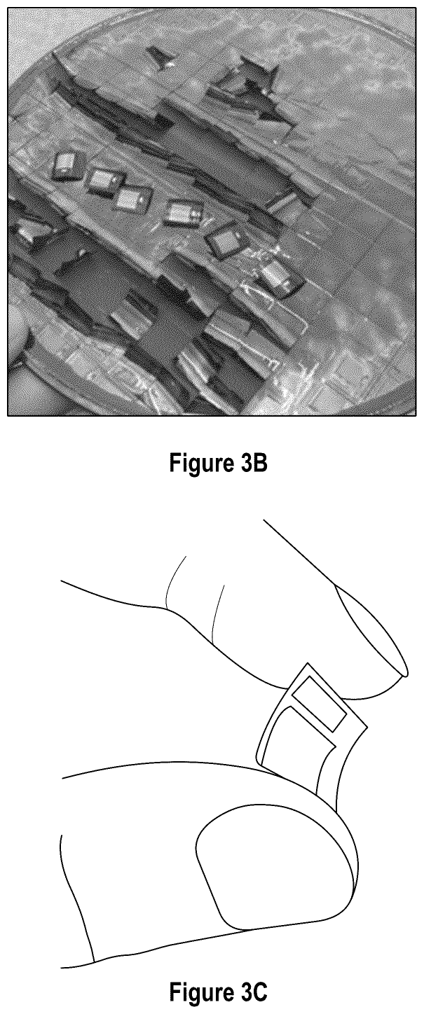

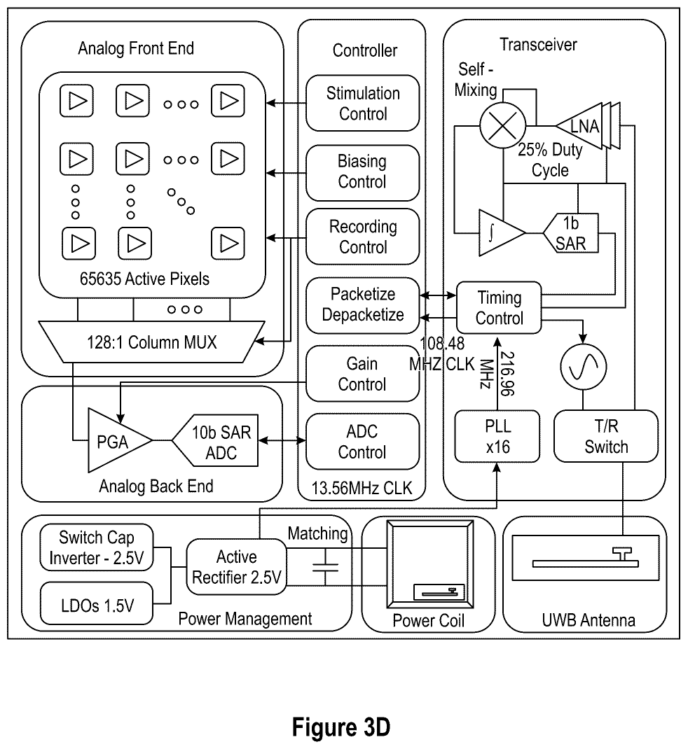

The BISC system can consist of the chip and a “relay station” which wirelessly powers and communicates with the chip. The MEA chip is implemented as a single integrated circuit chip 300 in a 0.13-μm CMOS technology (see FIGS. 3a-3d) and post-processed to add TiN electrodes to the surface, to thin the chip to approximately 15 μm total thickness, and passivate the chip. The thinned chip has a bending stiffness that goes inversely with the cube of the thickness. At 15 μm, the bending stiffness can be less than 5 μNm, making the device mechanically flexible and able to conform to the surface of the brain when implanted, which is the application for which BISC1 is designed. The relay station can be positioned up to several centimeters away from the chip for the wireless interface.

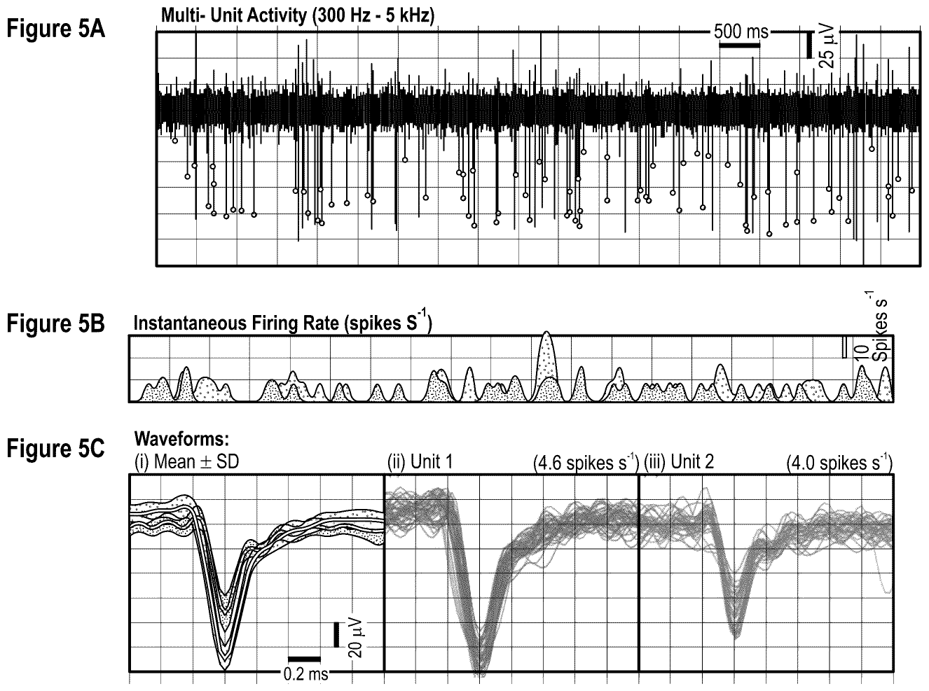

The relay station can be positioned directly outside the culture well as described herein. An ultra-wide-band (UWB) wireless data link with a center frequency is about 4 GHz with on-off-keying (OOK) modulation can be employed for communication. The relay-station powering coil inductively couples to the on-chip power coil at, e.g., about 13.56 MHz. The exemplary schematic of the on-implant electronics of BISC1 is shown in FIG. 3d. While BISC has 65,536 channels, because it has no data compression, recording can be limited to 256 simultaneous channels at 32 kS/s or 1024 simultaneous channels at 8 kS/s. FIG. 5 shows representative spiking behavior recorded with BISC1. This channel limitation can be addressed in BISC2 with on-chip compression, which can facilitate BISC2 to record from 16,384 channels at 32 kS/s.

Stimulation can be biphasic with three bits of amplitude control up to 100 μA per pixel, supporting stimulation magnitudes above the Shannon limit. (See, e.g., Ref. 25) Up to 1 mA can be sourced (or sunk) instantaneously in any pulse sequence, as can be limited by the peak power supported with the wireless powering. Nonetheless, a further stimulation configuration can be introduced with each pulse allowing the interleaving (time-division multiplexing) of multiple stimulation patterns while observing these maximum current limitations. In this exemplary way, in a pulse train with a 2 ms (500 Hz) period and 50-μs pulse width for each portion (anodic and cathodic) of the biphasic waveform, for example, 20 pulse trains can be interleaved. For 10 μA at 50-μsec anodic and cathodic periods, with full interleaving, approximately 2000 electrodes can be stimulated “simultaneously” at any time with a 500-Hz period.

The exemplary modelling according to the exemplary embodiments of the present disclosure can be based on prior work in developing state-of-the-art (SOTA) predictive models for area V1 and higher visual areas that can predict the responses of thousands of neurons in response to natural stimuli including video. (See, e.g., FIGS. 18-22). These digital-twin models can also account for eye movements and non-visual response modulation by behavioral states. (See, e.g., FIG. 18). It is possible to train these models end-to-end (data-driven) or use transfer learning using pretrained machine learning models trained on visual tasks like object recognition or segmentation (goal-driven models). (See, e.g., Ref. 21, 22 and 26).

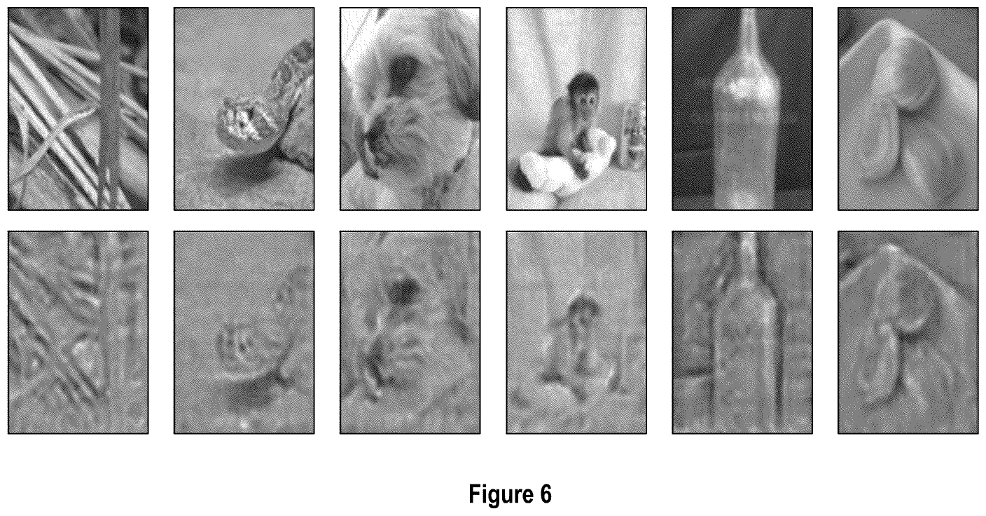

An exemplary method has been provided to invert these encoding models for decoding from populations. (See, e.g., FIG. 18). Specifically, to decode from the digital twin, an initially blank image can be optimized via gradient descent to produce predicted responses that matched the in vivo recorded responses while softly smoothing the image after each iteration to avoid unrealistic high-frequency details, (See, e.g., Ref. 18). These models can take the form of deep CNNs with a core network consisting of three convolutional layers shared among all recorded neurons, followed by a neuron-specific linear readout stage. In an analysis we refer to as “inception loops,” it is possible to use this exemplary model to determine maximum excitable inputs (MEIs), the image that maximally excites a target neuron, with a simple optimization procedure based on regularized gradient ascent. FIG. 6 shows to-be-published image reconstruction from ImageNet that comes from the inversion of such a digital-twin model of the visual cortex of the monkey based on BISC recorded data. The ability to reconstruct images is remarkable.

Culturing cells directly on planar MEAs (see, e.g., Ref. 27) can result in flattened structures as cell migrate and spread over the chip surface, altering the complex dynamics observed in spherical organoids. The impermeable planar MEAs can also induce hypoxia for cells on the surface, which are exactly those in the closest electrical contact with the MEA. In contrast, because the BISC interfaces according to the exemplary embodiments of the present disclosure (i) are wireless, (ii) can be produced at wafer scale, and (ii) require no wires or packaging, they can be easily incorporated into any culture wells, and many multiwall plates can be managed in parallel while providing many more channels than commercial systems. For these exemplary reasons, the BISC1 design according to the exemplary embodiments of the present disclosure can be be utilized.

Nonetheless, the challenges with culturing directly on planar MEAs has increased interest in culturing organoids directly on mesh electrode arrays which can support more natural spherical growth of the organoid. (See, e.g., Refs. 28-31). Mesh thicknesses vary but are generally on the order of several 10's of microns. The problem with these designs, however, can be that they are all passive electrode arrays, requiring the routing of a wire from each electrode out to external measurement electronics, severely limiting their scale to less than 100 electrodes in most cases.

Thus, according to the exemplary embodiments of the present disclosure, it is possible to provide BISC2, e.g., a further CMOS MEA interface that can support and/or facilitate an organoid growth while delivering a scale of, e.g., 16,384 electrodes. Based on the exemplary BISC1 design, the specification for this exemplary design are provided in Table 3 below.

TABLE
Exemplary specifications for the BISC1 and
BISC2 chips to be used in the studies.
Overall

| Chip size | BISC1: 12 mm × 12 mm | |
|---|---|---|
| | BISC2: 12 mm × 14 mm | |
| Chip thickness | 15 | μm |

| | |
|---|---|
| Number of electrodes | BISC1: 256 × 256 |
| | BISC2: 128 × 128 |
| Electrode size | 14 μm × 14 μm |
| Electrode pitch | BISC1: 29 μm |
| | BISC2: 58 mm |
| Electrode impedance | 160 kΩ @ 1 kHz |
| Total electrode array area | 7.4 mm × 7.4 mm |
| Silicon density in mesh | BISC1: 100% (no mesh) |
| | BISC2: 18% |

Power

| | | |
|---|---|---|
| Power link frequency | 13.56 | MHz |

| | |
|---|---|
| Transfer efficiency | 7% @, 1.5 cm |
| Total power | BISC1: 38.8 mW |
| | BISC2: 43.6 mW |

Data link

| Link type | UWB-IR | |
|---|---|---|
| Tra data rate | 100 | Mb/s |
| Receive data rate | 50 | Mb/s |
| Transmit energy per bit | 50 | pJ |
| Receive energy per bit | 200 | pJ |

Recording

| ADC resolution | 10 bits | |
|---|---|---|
| Number of ADCs | BISC1: 1 | |
| | BISC2: 64 | |
| Input-referred noise | 5.6 μVrms (10 Hz-4 kHz) | |
| Sample rate | BISC1: 8 kS/s (1024 channels); | |
| | 32 kS/s (256 channels) | |
| | BISC2: 32 kS/s (16,512 channels) | |
| High-pass cut-off | 5 | Hz |

Stimulation

| | | |
|---|---|---|
| Maximum current/channel | 100 | μA |
| Maximum current | 1 | mA |

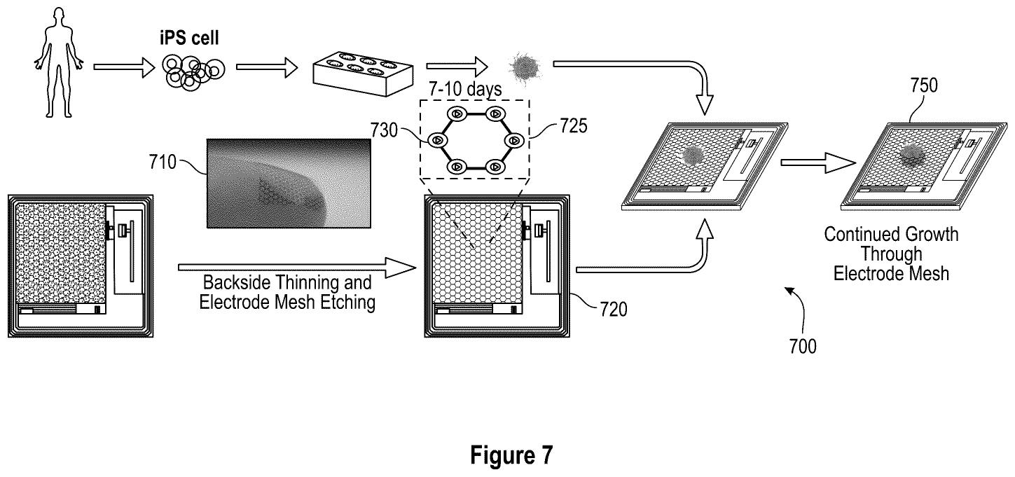

Important exemplary enhancements in BISC2 according to the exemplary embodiment of the present disclosure includes support for 32 kS/s recording across all, e.g., 16,384 electrodes through the incorporation of on-chip data compression and the use of a “honeycomb” meshed design, which can facilitate the organoid to “grow through” the MEA improving the quality of the interfaces. The mesh itself can be very flexible. For example, while not being stretchable, the mesh can conform to the organoid in a similar manner as the exemplary BISC design conforms to the pial brain surface (as shown in photo 710 of FIG. 7).

Other exemplary configurations can be possible using this exemplary design, including, e.g., stacking the chips back-to-back with the honeycomb holes through both chips. This exemplary configuration can facilitate electrodes to be provided on either side of the MEA plane. Multiple devices can also be stacked and spaced to facilitate the organoids to grow in three dimensions throughout multiple MEA planes. For example, stacking eight of these “bidirectional” planes can facilitate an organoid with, e.g., 262,144 electrode connections into the structure. Wireless operation uniquely makes such a module structure possible without the impediment that wires would likely create in producing these stacked structures. Time-division multiple access (TDMA) methods can be used to communication with more than one BISC2 chip.

### Exemplary Design of Exemplary Wireless MEA and Relay Station

FIG. 7 shows an exemplary BISC2 design/procedure 700 in accordance with the exemplary embodiment of the present disclosure in the context of culturing procedures directly on these devices.

Exemplary Chip modifications. As shown in FIG. 7, the pixel electronics can appear at the vertices of a hexagonal pattern 725 with electrodes 730 at each pixel site, with interconnect between them on the edges of the hexagons. This “open” structure can reduce the number of electrodes from 65,536 in BISC1 to 16,384 in BISC2. Such exemplary design, combined with exemplary design simplification at the pixel level made possible by the reduction in the number of electrodes, can facilitate the density of the electrode array to be reduced to approximately 18%, meaning that 82% of the electrode-array area will be taken up by the “holes” in the structure, which is comparable the the best passive meshes to-date. To support a 32 kS/s data rate over these channels, the number of ADCs should increase to 64.

For example, with an area of 500 mm×600 mm per ADC and a power dissipation of 75 μW, this can be accommodated on the chip with only slight increases in chip and power (see Table). It can be important to provide, e.g., 64× data compression on chip while retaining the ability to perform spike sorting. This can be done with activity-based spike compression similar to approaches used in the Neuralink design. (See, e.g., Ref. 32) For example, high-pass filtering of the channel can be employed, followed by a spike detection. Waveform pieces associated with the spikes, of adequate temporal resolution for spike sorting, can be transmitted.

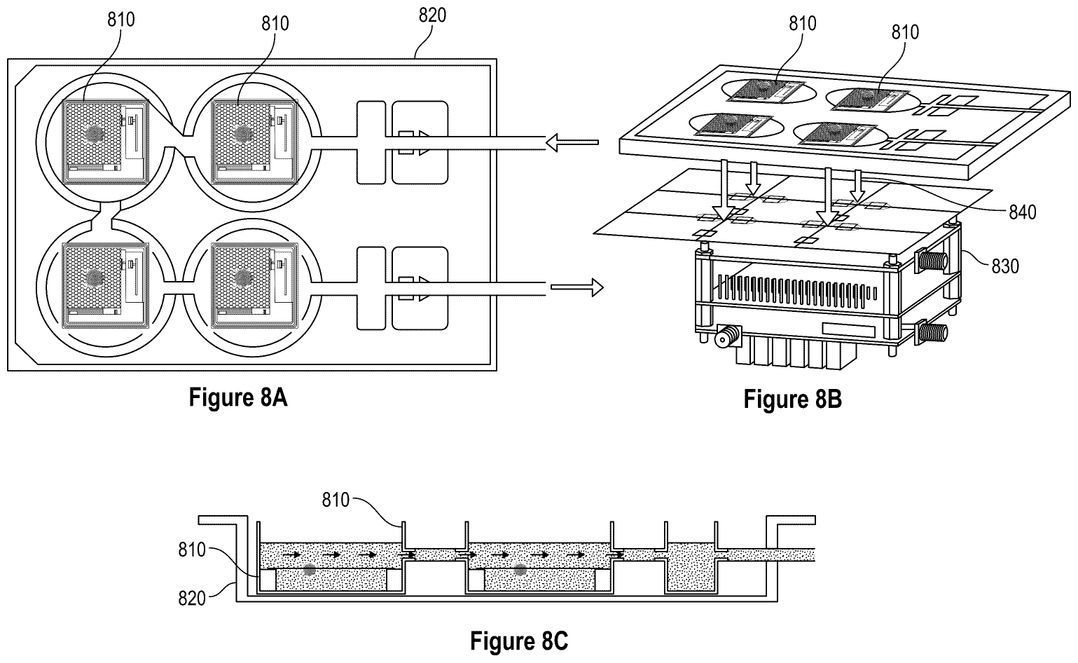

Exemplary relay station design to support four well locations. For example, perfusion plates 810 (as shown in FIGS. 8a and 8c) can be used to facilitate four wells 820 in a six-well plate to be set up for organoid growth. In this exemplary approach, there can be a continuous flow of media from one organoid reservoir to another. It was determined that organoids need to grow in groups, which can be accomplished using the exemplary design through contact through the media while still having only a single organoid per BISC2 well. The BISC2 chips can be suspended on a PDMS ring that can be provided and/or fabricated in each of these four wells 820. Organoids can then be able to grow through these MEA chips, which are also free to conform to the organoid.

The relay station 830 for BISC2 can have four antennas 840 coupling to the four-well plate system (as shown in FIG. 8b), facilitating communication to four chips in parallel. This board of the antennas 840 can connect with an HDMI cable to a processor board with a Zync SoC (FPGA and ARM processor). The board of the antennas 840 can be positioned in the incubator with the HDMI cable leaving the service port to be connected to the processor board outside. The Zync SoC can have a significant computation power with the ability to perform some of the spike sorting function described herein at improved energy efficiency over purely software implementations. Alternatively or in addition, these interfaces can be moved onto the BISC chip itself along with the training layers of the FORCE computing architectures described herein.

Exemplary Post-processing of Exemplary Wireless MEA. When the chip is provided for a commercial manufacturing, BISC2 can be be post-processed in a similar manner as that for the exemplary BISC1 design, including, e.g., the deposition of TiN electrodes, thinning of the substrate to give the chip mechanical flexibility, and passivation on the top- and back-side. To support the honeycomb structures, “holes” can be dry-etched into the chip prior to the passivation and thinning steps. The exemplary resulting chips 750 can have the form factor shown in FIG. 7.

Exemplary Culture Testing of Exemplary Design. Brain organoid growth from iPS cells generally can follow well-established protocols. (See, e.g., Ref. 33) For example, after the first three weeks, the organoids can be transferred to the BISC2 culture wells for subsequently development. It is possible to employ the same or similar poly-D-lysine coatings that have been used with BISC1 recordings. Laminin can also be utilized, as has been used for some of the passive mesh electrodes with organoids. (See, e.g., Ref. 28). The initial testing can be provided to ensure that the organoid continue to grow and develop over the course of months on the BISC2 chips and that it is possible to successfully record from them. The proven biocompatibility of the BISC1 design and our initial testing of BISC1 with organoid slices can indicate that these exemplary approaches are beneficial and successful.

### Exemplary Object 2. Providing an Accurate Deep Predictive in Silico Model of the Organoid

According to the exemplary embodiments of the present disclosure, it is possible to provide deep learning based predictive models of the organoid, based on building models for conveying complex information into the the cortex. For example, inception loops (See, e.g., Refs., 18, 19 and 23) have been discussed that integrate large-scale neural data with deep learning models to uncover novel brain function principles and solve high-dimensional nonlinear optimization problems. These neural predictive models (or “digital twins”) allow essentially unlimited in silico experiments to generate hypothesis which can be verified in vivo. According to the exemplary embodiments of the present disclosure, it is possible to train deep learning models to predict the activity of the organoid recorded from thousands of channels in response to external multi-channel electrical stimulation. Such exemplary digital twins can be utilized to better initialize the organoid computer, to perform in silico modeling of the organoid computer, and to track learning in the organoid as a function of time.

To that end, the exemplary BISC2 system facilitates an automatic gathering of data over long time periods in order to further understand spontaneous and induced changes in functional connectivity in organoids. Such data facilitates a development of detailed in-silico models in this aim, which will facilitate us to better understand the structure and function of the organoid and how these evolve over time, particularly in response to the feedback learning stimuli as discussed herein and shown in FIGS. 1A and 1B. For example, these exemplary models can facilitate a more effective “set-up” of the exemplary CMOS-organoid processors with proper selections of input and outputs to the organoid for our trainable layers as described herein. Then, as feedback stimuli and input patterns are applied in training, the functional connectivity changes are understood in response to these stimuli, resulting in a better understanding of how neural systems process and potentially store external information.

It is possible to train, e.g., two types of in-silico neural networks, a deep RNN, that can follows the approaches previously used to develop the CNNs for visual cortex, and a transformer model, which has been pursued for these types of applications although which can easily “evolve” along with the organoid as new data are used in its training. In both exemplary cases, functional connectivity can be assessed in the intrinsic activity of no-stimulation recordings as well as in evoked responses. It is possible to perform this exemplary modelling over the largest set of electrodes possible, which can be subsetted in the compute model set-up as described herein.

According to the exemplary embodiments of the present disclosure, it is possible to provide exemplary interfacing approaches for extracting data from the organoid and applying stimulus. Once these interfaces are established, it is possible to perform the model development. For example, data collected can be with organoid slices on BISC1 and progressed to continuous monitoring of full organoids as the BISC2 hardware comes on-line.

### Exemplary Encoding and Decoding Approaches

Type of neural activity used to generate outputs. There can be two or more types of neural signals that can be recorded from the organoids, spiking behavior and LFPs. LFPs results from superimposition of ongoing spiking currents and thus are a more indirect measure of evoked activity. (See, e.g., Ref. 34). As a result, the exemplary analysis can be focused on spiking behavior.

Spiking behavior can be measured as single-unit activity (SUA) or multi-unit activity (MUA), where SUA is known to come from a single neuronal source while an MUA does not identify a single source of the measured action potential. SUAs give the highest granularity in the read out but require spikes to be sorted, which is a computationally intensive process. Some brain-machine interfaces have successfully operated on unsorted spikes (see, e.g., Ref. 35). Nonetheless, it is possible to assume that spike sorting may be required in the interfacing pipeline. Low latency can be important for the feedback paths in our compute model. An exemplary procedure can be provided to perform spike sorting in real time, achieving latencies that match single synaptic time delays.

It is possible to determine whether this enhanced granularity in the readout significantly enhances predictive model accuracy in the digital twin when compared to an MUA readout obtained by conventional root-mean-squared-based thresholding of the measured signals. These interface computations be performed with software implementations, and then be moved to the relay station hardware described herein. Further, if these can be made sufficiently “light weight,” they can be supported on the BISC hardware directly.

Input and output encoding and decoding. Another exemplary aspect can be an appropriate encoding of stimulation inputs and proper decoding of recorded outputs. For example, these temporal characteristics can be consistent for both inputs and outputs. Spike amplitude is not likely to be used because this is a less well-defined encoding and because the exact coupling of the electrodes to the target neuron in the reservoir can be indeterminate. It is also unlikely to utilize detailed spike waveforms (see, e.g., Ref. 36), or vary the duration of anodic and cathodic phases in biphasic stimulation because they can require considerable computational resources at the interfaces. Instead, it is possible to assess the use of spike frequency and spike-train duration (or number of spikes) for encoding and decoding. It is possible to utilize different variations of these encoding and decoding strategies to assess which method is most effective in the context of training the exemplary digital twin models, which can be assessed in silico from the same datasets.

Exemplary Deep Learning digital twins for the organoids. While CNNs can be appropriate models for image recognition tasks, a model of the organoid that is able to capture its more natural temporal dynamics and its ability to process time-series data is usable according to the exemplary embodiments of the present disclosure.

Thus, in accordance with the exemplary embodiments of the present disclosure, it is possible to utilize and/or provide two types of digital twins. The first type can be an RNN, which can process sequences by maintaining a hidden state that is updated at each step of the sequence, effectively facilitating this state to “remember” information from the previous steps. There can be several possible RNN variants like long short-term memory (LSTM) and gated recurrent units (GRU) which seek to address the vanishing gradient problem which lead to difficulties in capturing long-term dependencies. In addition to these more traditional RNNs, it is possible to utilize liquid time constant (LTC) networks, also known as liquid neural networks (LNNs), continuous-time RNN inspired by LSMs which have found application in autonomous self-driving cars. (See, e.g., Refs. 37 and 38)

In addition to RNNs, it is possible to utilize exemplary transformer models which have become the de facto standard for a wide range of nature language processing (NLP) tasks and are increasingly being used in other domains like computer vision. They are effective in understanding the context and relationships within data and can be used with time-series data as well. Transformers are based on the self-attention mechanism, which can facilitate the model to weigh the importance of different parts of the input data. Such transformers can process the entire input data in parallel, making them highly efficient and scalable. The transformers can include an encoder and decoder architecture, though variants like GPT (e.g., used in generative tasks) use only the decoder, and BERT (e.g., used in understanding tasks) use only the encoder. These configurations can be considered since the transformers can capture long-range dependencies without being limited by sequence length, due to the self-attention mechanism. They are highly parallelizable, leading to significant speedups in training and inference compared to RNNs. According to the exemplary embodiments of the present disclosure, optimized RNN architectures can be provided to predict the dynamics of large-scale population activity in the cortex in response to dynamic inputs (natural movies), and we have also begun training transformer networks for this purpose as well. (See, e.g., Ref. 39).

These exemplary models can be provided using, e.g., the full complement of electrodes interfacing to the organoid, each used for both stimulation and recording. Stimulation patterns can be chosen to provide an “initial-state” model to be used for the interface selection step (input, output, feedback input, feedback output) for the CMOS-organoid processor as described herein. These exemplary patterns can at least involve, e.g., all combinations of single-electrode inputs at different encoded intensities, and can include combinations of multi-electrode stimulation as well. Subsequent input patterns can be provided from the training datasets for the organoid-CMOS processor.

Exemplary RNN model. It is possible to train a RNN model by generating in-silico models of mouse visual cortex. (See, e.g., Ref. 39). In addition to GRU and LSTM approaches, LNNs can be considered. LNNs can dynamically change the number of neurons and connections per layer based on the incoming data, facilitating LNNs to be more interpretable and adaptable to changing data even after the training phase. Such architectures have been successful in mimicking the complex dynamics of the nematodes C. elegans. (See, e.g., Refs. 40 and 41). These exemplary networks can model in continuous time (potentially) chaotic characteristics captured in the form of nonlinear ordinary differential equations for a vector field of hidden states x according to dx/dt=f(x(t),i(t),θ), where i(t) is the time-dependent input and θ are model parameters.

Exemplary Transformer model. In addition to RNNs, exemplary digital twins model can be provided using autoregressive transformer-based model, similar to large language models (LLMs) that have recently achieved success in platforms such as ChatGPT. The choice of autoregressive transformer-based model can be motivated by the need in sequential processing where each output depends on previous ones (see, e.g., Ref. 42) with attention mechanisms adapted for multidimensional data. To ensure efficiency and performance of our model, it is possible to decompose the attention mechanism into separate temporal and spatial components. (See, e.g., Refs. 43 and 44).

The organoid data can be converted into a 2D array of tokens, where each row corresponds to a neuron, each column corresponds to a time window, and a token corresponds to aggregated firing information of the corresponding neurons within a particular time window (or other suitable decoding based on the description herein). The response from an organoid can generate extremely large data sets. Therefore, the transformer's attention blocks can be factorized into alternating blocks of temporal-only and spatial-only attention and combined with factorized positional embeddings can be learned per-neuron and rotary temporal parts. (See, e.g., Refs. 42-44). The rotary temporal procedure can encode positional information into the transformer model in a way that can enhances the model's ability to understand the relative positions of elements within a sequence for efficient and faster computation. (See, e.g., Ref. 45). This can occur with a special rotational matrix, which can encode the absolute position of tokens while simultaneously capturing the relative positional dependencies within the self-attention mechanism. In particular, the rotary temporarily can ensure that the self-attention mechanism's inner product between query and key vectors accounts for their relative positions directly. This can achieved by a function that only considers the embeddings of the tokens and their relative positions, aiming to encode positional information in a relative manner, in contrast to traditional transformers which simply leverage positional information to understand the order and relative positions of tokens in a sequence.

### Exemplary Object 3. Providing Exemplary Computing Models Based on Supervised Learning

Beginning with an RC model, it is possible to train linear classifiers at both the input and output. The input classifier will be trained by back-propagation of errors in the digital twin model. It is possible to improve this exemplary model to include training the feedback path shown as shown in FIG. 3. For example, the digital twin model can be utilized to decide on the number of choices of input and output connections into this model. The number of connections required into the organoid can be determined as the organoid learns the task through the feedback path. The MNIST and ImageNet AI benchmarks can further be utilized for an additional improvement of the exemplary model.

To that end, exemplary CMOS-organoid computing models according to the exemplary embodiment of the present disclosure can be provided which can include an exemplary reservoir computing model shown in FIG. 1B with the addition of feedback back loops 160, 170 into the network. In another exemplary embodiment, reservoir computing trained an output classifier with ridge regression with no feedback, the success of these approaches can be very dependent on the “initial” state of the reservoir itself. (See, e.g., Ref. 46). Given the high spontaneous activity of brain organoids, e.g., this exemplary approach would be less successful for organoids that have significant spontaneous dynamic behavior. Instead, it is possible to utilize the exemplary embodiments of the methods that include feedback(s) and on-line learning through weights that are controlled in the CMOS layer. These exemplary techniques can take advantage of these (potentially) chaotic characteristic of the organoid. A more generalized supervised RNN learning approach can be utilized as the organoid itself learns using the same feedback paths.

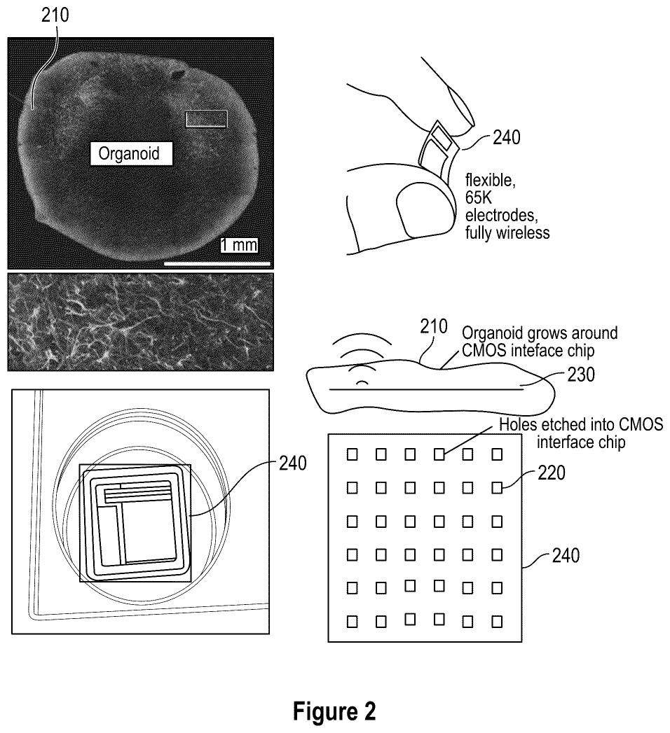

Exemplary FORCE-based training with feedback. Exemplary training can follow the FORCE model. (See, e.g., Ref. 16). All or most variables can follow the encodings described herein. The readout can be linearly defined as yₒᵤₜ(t)=Wₒᵤₜ rₒᵤₜ(t), where rₒᵤₜ(t) are electrode connections to the reservoir as noted in FIG. 2. At the same time, there can be a feedback network that takes other outputs rₒᵤₜ^{fb}(t) and maps these back to rᵢₙ^{fb}(t) with the linear weights rᵢₙ^{fb}(t)=W_{fb}rₒᵤₜ^{fb}(t). With the output defined, it is possible to establish the required target function f(t) for this output which can depend on the inputs xᵢₙ(t), which also map into the reservoir with a set of linear weights rᵢₙ(t)=Wᵢₙ xᵢₙ(t). Training of Wₒᵤₜ can follow a modified recursive least squares (RLS) algorithm/procedure. An error can be defined by e⁻(t)=Wₒᵤₜ(t−Δt)rₒᵤₜ(t)−f(t). The exemplary weights can then be updated according to Wₒᵤₜ(t)=Wₒᵤₜ(t−Δt) ˜P(t)rₒᵤₜ(t)e₋^{T}(t). P(t) is updated at the same time as the weights according to

$$P ( t ) = P ( t - Δ t ) - \frac{P ( t - Δ t ) {r}_{out} ( t ) {r}_{out}^{T} ( t ) P ( t - Δ t )}{1 + {r}_{out}^{T} ( t ) P ( t - Δ t ) {r}_{out} ( t )} .$$

P(0) is set to I/α, where I is the identity matrix and α is a constant parameter. The same updates are performed on W_{fb} according to W_{fb}(t)=W_{fb}(t−Δt)−P(t)rₒᵤₜ^{fb}(t)e₋^{T}(t). The error after training at this time step become e⁺(t)=e⁻(t)(1−r^{T}(t)P(t)r(t)). Training ends when |e⁺(t)|/|e⁻(t)|≈1. It is possible to use the initial-state digital-twin model described herein to determine the best initial electrode choices for rₒᵤₜ, rᵢₙ, rᵢₙ^{fb}, and rₒᵤₜ^{fb}.

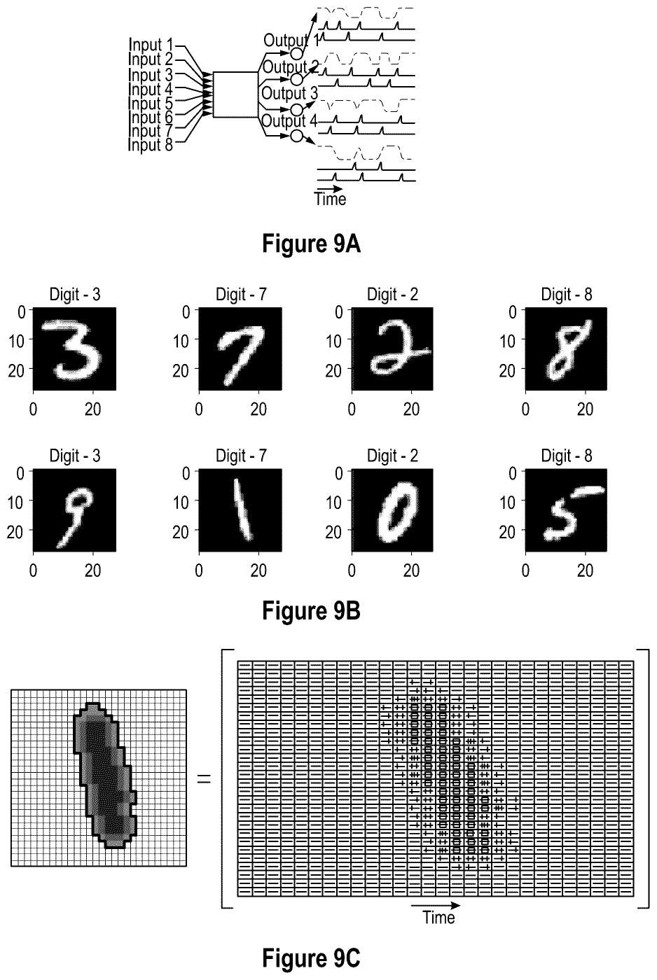

Exemplary Training Datasets. For example, simple model trainings can be utilized that show the ability of the organoid to track time-series data. An example of one of these tests is shown in FIG. 9a (see, e.g., Ref. 16), which takes the form of a simple Boolean system that could be easily created with CMOS logic and flip-flops. In this example, it is possible to get the organoid to operate as a four-bit memory that is robust to input noise. There are eight inputs 905 that are functionally divided into pairs. The input values are zero except for short pulses that act as ON and OFF commands. Input 1 (Input 2) is the ON (OFF) command for Output 1. Similarly, the other input pairs control corresponding output 910. More complex examples can be provided that build on these simpler ones.

The next set of tests can involve image classification with the data presented as scan-line data to the organoid. The simplest of these image classifications can be the MNIST dataset 920 as shown in FIG. 8b. For example, the choice of MNIST data set can be motivated by simplicity of the image sets 920, where each image can consist of only 28×28 grayscale pixels, and each pixel intensity is represented by value from 0 to 255 (0 is black, 255 is white, and values in between represent shades of gray). The pixel intensity scale can be encoded in spike trains as developed herein In the simplest form, the entire image is flattened to 784 pixel inputs. Ten outputs can be used to identify the digit. If fewer inputs are desired, then the image 930 can be sent to the organoid in 28 inputs on a row basis with a column-wise scan line, as shown in FIG. 9c. This time-series encoding can take advantage of the ability of the organoid to track such time-series data. It is possible to consider more complex image recognition datasets 940, such as ImageNet (see, e.g., Ref. 9), as shown in FIG. 9c.

The exemplary CMOS-organoid processor can be provided in stages. It is possible to consider performance in the absence of feedback. It is also possible to then add trained feedback to show the significant improvements in performance that come with this addition. Further, it is possible to consider how supervised learning can occur in the organoid as a result of this feedback, driven by distillation of input and output connections to the organoid. This can be performed with organoid slices and BISC1 and then progress to BISC2.

Exemplary Reservoir computing model with no feedback. In the absence of changes in the organoid itself, the organoid can simply provides a reservoir consisting of RNNs with directed connections, fading memory, and complex spatiotemporal dynamical features, as shown in FIG. 1A. This exemplary model with no feedback can be utilized in accordance with certain exemplary embodiments of the present disclosure, and there will only be mapping to the rᵢₙ and rₒᵤₜ connections to the organoid.

Exemplary Input/Output Configuration. It is possible to utilize the initial-state in-silico models of the organoid described herein to decide on the best choices for rᵢₙ and rₒᵤₜ. Previous work using FCMs in organoids shows a characteristic heavy-tailed distribution. (See, e.g., Refs. 7 and 47). The strong pairwise couplings that inhabit the tail of this distribution belong to a subset of neurons that form a tightly interconnected network of highly correlated neurons with highly consistent repetitive firing patterns, forming a stable “backbone” for each population burst. (See, e.g., Ref. 47). This backbone constitutes a lower dimensional manifold in the high-dimensional state space of the organoid that seems to be present in most organoid structures. It is likely that the more effective couplings to the organoid can be those that access this lower dimensional manifold. Meanwhile, plasticity dependent learning might be more likely to occur among neurons that are not part of this rigid backbone. To understand this, a comparison can be performed on the computational performance when encoding the exemplary inputs to this specific selection of neurons compared with encoding our inputs specifically to the remaining neurons. These considerations will also apply to the selection of feedback inputs. Thus, the functional role of these repetitive firing patterns within organoids can be determined.

Exemplary Training input and output layers. In the absence of feedback, the FORCE-based training can be performed on the output layer 150 as shown in FIG. 1A. In addition, backpropagation and gradient ascent in the RNN digital twin model can be used to train the input layer as well, e.g., not being possible in the absence of an in-silico model. Inversion of transformer-based models can be considered. (See, e.g., Ref. 48). For example, in the absence of feedback, the chaotic dynamics of the organoid can possibly affect performance. All of the input and output patterns recorded in these studies revert back to be employed in continuous model refinement.

Exemplary Reservoir computing model with feedback and supervised learning. It is possible to introduce the Web path shown in FIG. 3. In this exemplary way, it is possible to provide a feedback input to the organoid itself for supervised learning, and this can also provide an ability to control any chaotic dynamics in the organoid that are not possible with input and output layer training alone. It is possible to use the digital twin to select rᵢₙ^{fb} and rₒᵤₜ^{fb}. In the absence of changes in the RNN of the organoid itself, it is likely that the best choices for rᵢₙ^{fb} and rₒᵤₜ^{fb} can be those that couple to the lower-dimensional manifolds with the same considerations we used to determine rᵢₙ and rₒᵤₜ. However, to drive learning in the organoid itself, it is possible to find weaker connections to be more affected by this training and better suited as choices for the feedback network as described herein. Once such a closed-loop environment for the organoid is determined, it can be asked as to the extent to which the organoids themselves have “consciousness.”

Exemplary Distillation of the organoid interfaces. It is likely that the organoid itself can learn and possesses long-term memory. If so, it is possible to employ these features as part of the computational models. The exemplary feedback in the exemplary FORCE model can facilitate the external stimulation through rᵢₙ^{fb} to evoke states of enhanced plasticity in the organoids. By letting the amount of error determine the amount of feedback, it is possible to evoke enhanced plasticity specifically in moments when the organoids performs poorly. It is unclear if rᵢₙ^{fb} should be directed to inputs of the stable backbone unit sequence or to the more variably firing non-rigid units to enhance organoid plasticity. This can be determined using the digital twin model. As the organoid learns, the dimensionality reduction can be possible in all the connections to the organoid, including rᵢₙ, rₒᵤₜ, rᵢₙ^{fb} and rₒᵤₜ^{fb}. It is possible to begin to remove connections into the organoid through analysis of the weight matrices. For example, if Cᵣ is the correlation matrix for rₒᵤₜ, then it is possible to remove the rows of Wₒᵤₜ (say wᵢ) in a way that retains maximum signal variance in yₒᵤₜ=Wₒᵤₜ rₒᵤₜ for orthonormal Wₒᵤₜ. as given by [symbol] [yₒᵤₜ^{T}yₒᵤₜ]= [symbol] [rₒᵤₜ^{T}Wₒᵤₜ^{T}Wₒᵤₜrₒᵤₜ]. To do this, it is possible to choose the wᵢ which are outside the dominant eigenspaces of Cᵣ. As dimensionality is reduced in any of the connections to the organoid, errors will result which will be fed back into the organoid through rᵢₙ^{fb}, hopefully driving the organoid to further dimensionality reduction.

Exemplary Stimulation. In addition to long-term memory, BISC2 can provide the potential to record and stimulate the organoid through its development, providing opportunities to consider how the reservoir changes during this development over months and how stimulation or pharmacological treatments may direct this process. This can provide insight into how the intrinsic activity of the culture evolves over time (maturation, circadian rhythms) and can take advantage of the capabilities of the chips to automatically record over prolonged periods of time. For example, neurons can change location during development, which can be handled in the exemplary modeling.

### Exemplary Object 5—Exemplary Benchmarking

This exemplary object is associated with establishing quantifiable comparisons between hybrid CMOS/brain organoid computing and the most advanced all-CMOS neuromorphic systems available on comparable computing benchmarks. This is the best way to quantify the engineering impact of the systems developed here.

To that end, benchmarking the energy efficiency in both training and inference possible with the organoid-CMOS processor compared to all-CMOS implementations, in the form of SNNs, can be important to establishing the technological significance of the exemplary embodiments of the present disclosure. It is beneficial to achieve energy efficiency gains on the order of 100× in training at the same accuracy. This exemplary benchmarking can utilize techniques to assay glucose utilization and the energy consumed in the interface electronics in performing the benchmarks, as described herein.

Exemplary Energy costs of organoid computing. It can be beneficial to quantitatively estimate the energy dissipated in the exemplary organoid computing models and to correlate them with known physical limits of computation. (See, e.g., Ref. 67 and 68). It is possible to determine how resources can scale to larger models with higher degrees of randomness and structural complexity. Glucose assays can be used for energy monitoring in the organoid. It is also possible to separately measure the energy utilization in the CMOS interface electronics.

Benchmarking against all-CMOS neuromorphic designs. An exemplary comparison can be performed for energy-efficiency training benchmarks, such as energy per accuracy, with state-of-the-art semiconductor SNN processors. It is possible to focus on the Loihi 2 processor from Intel because it has more hardware support for on-chip learning than other comparable analog or digital SNNs. The programming of MNIST for Loihi 2 has been well-documented (see, e.g., Ref. 69 (and can be used as a comparison example with the same input datasets applied to the organoid-CMOS process. For the case of MNIST, for example, inputs can take the form of the row-wise scans with stacked vectors as inputs as shown in FIG. 9c.

It is expected that these comparisons can be favorable. The supervised training of SNNs can be computationally and memory intensive. The exemplary methods can use back propagation through time (BPTT) with surrogate gradients (SG). (See, e.g., Refs. 70-73). These exemplary approaches can provide the iterative expressions that describe the behavior of spiking neurons, backpropagate the errors through time (see, e.g., Ref. 74), and can use surrogate derivatives to approximate the gradient of the spiking function (see, e.g., Refs. 75-82). During training, they can utilize significant memory that is proportional to the number of time steps.

Organoids can be populated with a remarkably broad range of cells that resembles brain-cell diversity, and have both spiking patterns and local field potentials (LFPs) that resemble activity in the brain. This spontaneous activity can occur in the absence of sensory or motor states invariably present in brains associated with a body. Activity in the brain organoid can be an isolated intrinsic framework upon which experience can likely be encoded. When an experience is presented to an animal brain, it is likely encoded by changing synaptic weights and is stored by instantiating a corresponding connectivity map known as an engram. To review these phenomena, according to exemplary embodiments of the present disclosure, as shown in FIG. 2, it is possible to grow individual organoids 210 around wireless high-electrode-density CMOS multi-electrode arrays (MEAs) 240, thereby facilitating recording(s) from numerous (e.g., tens of thousands) of its cells on millisecond time scales. An exemplary well plate 230 with wireless CMOS MEA embedded therein, according to exemplary embodiments of the present disclosure, is shown in FIG. 2. This exemplary MEA device 240 can also stimulate the organoid, providing full input-output capabilities. The exemplary MEA device 240 can include flexible (e.g., 65K) electrodes, which can be fully wireless.

Exemplary Wireless MEA Technology. An exemplary wireless chip detection of activity can provide a previously-unavailable way to interface to brain organoids recording(s), facilitating them to grow around these devices without concerns about wired connections. By organizing multiple wireless chips between stacked organoid sections, e.g., three-dimensional structures can be formed. The exemplary size of individual organoids can be limited by the lack of vasculature. Perfusion systems to keep organoids alive can be more easily managed with an absence or a reduction of wires. As shown in FIG. 2, “holes” 220 can be etched into the CMOS MEA 240 so as to facilitate the organoid to grow through and around it. For example, the CMOS MEA 240 can also thinned and CMOS chips can be bonded back-to-back to facilitate electrode interfaces on both sides of the CMOS MEA 240.

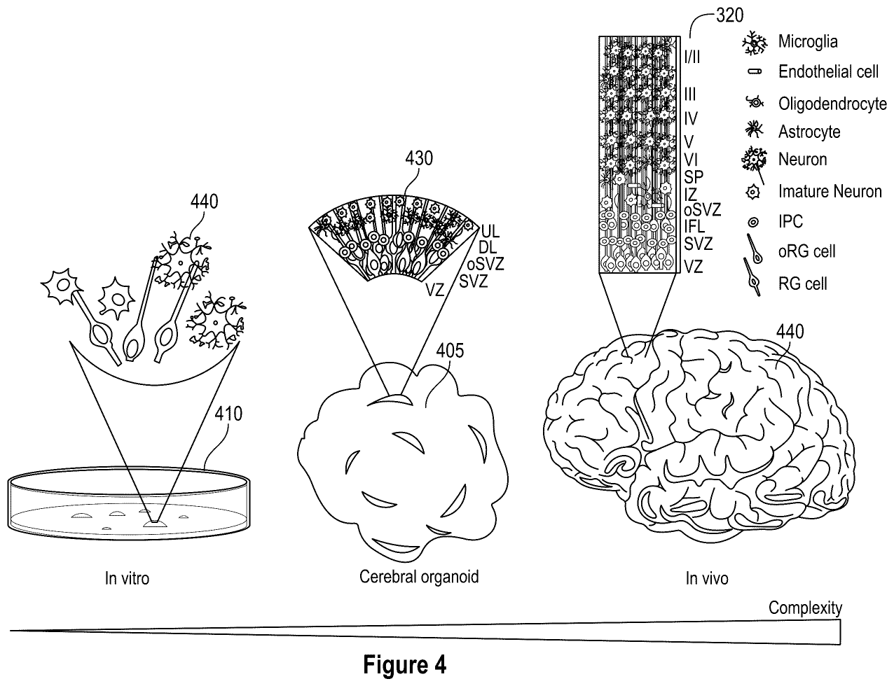

Organoids as Exemplary High-Dimensional Reservoirs. Turning back to FIG. 4, a large organoid set 420 can have many of the structures present in the human brain 400, as shown in FIG. 4. In addition or alternatively, a smaller set 420 can be provided in the cerebral organoid 405, and yet a smaller set 340 in an in-vitro container environment 410, as shown in FIG. 4. Indeed, the complexity increases when proceeding from the in vitro-container environment 410 to the cerebral organoid and yet more to the brain 400.

According to exemplary embodiments of the present disclosure, according to the exemplary embodiments of the present disclosure, as shown in FIG. 1, the high-resolution organoid-CMOS interfaces can operate as a high-dimensional reservoir for information processing. In the absence of long-term memory in the organoid, most or all training can occur in either the input layer 130 or an output layer 150, as illustrated in FIG. 1A. The traditional approach to reservoir computing can involve training of the output layer through a linear regression. Modern dynamics-based analysis methods—such as, e.g., Cantor embedding and Wasserstein metrics—can be used to probe for the emergence of predictive states. (See, e.g., Refs. 2 and 4).

Training of the input layer 130 can also be performed, one of the goals in neuroscience has been to map high-dimensional inputs 140 onto the brain naturally, for example, as it occurs with visual stimuli. According to the exemplary embodiments of the present disclosure, exemplary input-layer training can utilize an exemplary technique called “inception loops”. In this exemplary approach, e.g., it is possible to initially collect large-scale time series from a large number of “output” neurons in the organoid that are generated in response to different patterns of stimulation. (See Ref. 7). Based on such recording responses, an exemplary predictive model can be used to train the input layer 130 using back propagation, gradient ascent, or Bayesian structural inference based on the activity of specific output neurons. (See, e.g., Ref. 8). Different combinations of the training of the input and output layers 130, 150 can be employed.

Possibilities for Exemplary Learning and Memory in the Organoid. According to certain exemplary embodiments of the present disclosure, as shown in FIG. 1, the organoid can simply provide a reservoir 110 which can include random neural networks with directed connections, fading memory, and complex spatiotemporal dynamical features. For example, learning and long-term memory in the organoid itself is not necessary. In other exemplary embodiments of the present disclosure, it is possible to take advantage of the fact that the organoid can learn and possesses memory. In this exemplary case, it is possible to employ these exemplary features in the exemplary computational models. In this exemplary manner, reinforcement learning through the dynamic architecture of memory existing on hyperplanes within the space of the reservoir 110 can be used.

Energy costs of Exemplary Organoid Computing. The thermodynamic costs—energy dissipated and entropy produced—of these exemplary organoid-CMOS computing models according to exemplary embodiments of the present disclosure can be significantly lower than even the most advanced spiking neural network designs. (See, e.g., Refs. 1-3). These exemplary approaches according to the exemplary embodiments of the present disclosure can scale to larger models with higher degrees of randomness and structural complexity.

In this description, numerous specific details have been set forth. It is to be understood, however, that implementations of the disclosed technology can be practiced without these specific details. In other instances, well-known methods, structures and techniques have not been shown in detail in order not to obscure an understanding of this description. References to “some examples,” “other examples,” “one example,” “an example,” “various examples,” “one embodiment,” “an embodiment,” “some embodiments,” “example embodiment,” “various embodiments,” “one implementation,” “an implementation,” “example implementation,” “various implementations,” “some implementations,” etc., indicate that the implementation(s) of the disclosed technology so described may include a particular feature, structure, or characteristic, but not every implementation necessarily includes the particular feature, structure, or characteristic. Further, repeated use of the phrases “in one example,” “in one exemplary embodiment,” or “in one implementation” does not necessarily refer to the same example, exemplary embodiment, or implementation, although it may.

As used herein, unless otherwise specified the use of the ordinal adjectives “first,” “second,” “third,” etc., to describe a common object, merely indicate that different instances of like objects are being referred to, and are not intended to imply that the objects so described must be in a given sequence, either temporally, spatially, in ranking, or in any other manner.

While certain implementations of the disclosed technology have been described in connection with what is presently considered to be the most practical and various implementations, it is to be understood that the disclosed technology is not to be limited to the disclosed implementations, but on the contrary, is intended to cover various modifications and equivalent arrangements included within the scope of the appended numbered claims. Although specific terms are employed herein, they are used in a generic and descriptive sense only and not for purposes of limitation.

The foregoing merely illustrates the principles of the disclosure. Various modifications and alterations to the described embodiments will be apparent to those skilled in the art in view of the teachings herein. It will thus be appreciated that those skilled in the art will be able to devise numerous systems, arrangements, and procedures which, although not explicitly shown or described herein, embody the principles of the disclosure and can be thus within the spirit and scope of the disclosure. Various different exemplary embodiments can be used together with one another, as well as interchangeably therewith, as should be understood by those having ordinary skill in the art. In addition, certain terms used in the present disclosure, including the specification and drawings, can be used synonymously in certain instances, including, but not limited to, for example, data and information. It should be understood that, while these words, and/or other words that can be synonymous to one another, can be used synonymously herein, that there can be instances when such words can be intended to not be used synonymously. Further, to the extent that the prior art knowledge has not been explicitly incorporated by reference herein above, it is explicitly incorporated herein in its entirety. All publications referenced are incorporated herein by reference in their entireties.

Throughout the disclosure, the following terms take at least the meanings explicitly associated herein, unless the context clearly dictates otherwise. The term “or” is intended to mean an inclusive “or.” Further, the terms “a,” “an,” and “the” are intended to mean one or more unless specified otherwise or clear from the context to be directed to a singular form.

This written description uses examples to disclose certain implementations of the disclosed technology, including the best mode, and also to enable any person skilled in the art to practice certain implementations of the disclosed technology, including making and using any devices or systems and performing any incorporated methods. The patentable scope of certain implementations of the disclosed technology is defined in the claims, and may include other examples that occur to those skilled in the art. Such other examples are intended to be within the scope of the claims if they have structural elements that do not differ from the literal language of the numbered paragraphs, or if they include equivalent structural elements with insubstantial differences from the literal language of the claims.

### EXEMPLARY REFERENCES

The following reference is hereby incorporated by references, in their entireties:
1. Schemmel, J., D. Brüderle, A. Grübl, M. Hock, K. Meier, and S. Millner. A wafer-scale neuromorphic hardware system for large-scale neural modeling. in 2010 IEEE International Symposium on Circuits and Systems (ISCAS). 2010. IEEE.
2. Benjamin, B. V., P. Gao, E. McQuinn, S. Choudhary, A. R. Chandrasekaran, J.-M. Bussat, R. Alvarez-Icaza, J. V. Arthur, P. A. Merolla, and K. Boahen, Neurogrid: A mixed-analog-digital multichip system for large-scale neural simulations. Proceedings of the IEEE, 2014. 102 (5): p. 699-716.
3. Furber, S. B., D. R. Lester, L. A. Plana, J. D. Garside, E. Painkras, S. Temple, and A. D. Brown, Overview of the SpiNNaker system architecture. IEEE transactions on computers, 2012. 62 (12): p. 2454-2467.
4. DeBole, M. V., B. Taba, A. Amir, F. Akopyan, A. Andreopoulos, W. P. Risk, J. Kusnitz, C. O. Otero, T. K. Nayak, and R. Appuswamy, TrueNorth: Accelerating from zero to 64 million neurons in 10 years. Computer, 2019. 52 (5): p. 20-29.
5. Davies, M., N. Srinivasa, T.-H. Lin, G. Chinya, Y. Cao, S. H. Choday, G. Dimou, P. Joshi, N. Imam, and S. Jain, Loihi: A neuromorphic manycore processor with on-chip learning. Ieee Micro, 2018. 38 (1): p. 82-99.
6. Orchard, G., E. P. Frady, D. B. D. Rubin, S. Sanborn, S. B. Shrestha, F. T. Sommer, and M. Davies. Efficient neuromorphic signal processing with loihi 2. in 2021 IEEE Workshop on Signal Processing Systems (SiPS). 2021. IEEE.
7. Sharf, T., T. van der Molen, S. M. Glasauer, E. Guzman, A. P. Buccino, G. Luna, Z. Cheng, M. Audouard, K. G. Ranasinghe, and K. Kudo, Functional neuronal circuitry and oscillatory dynamics in human brain organoids. Nature communications, 2022. 13 (1): p. 4403.
8. Baldominos, A., Y. Saez, and P. Isasi, A survey of handwritten character recognition with mnist and emnist. Applied Sciences, 2019. 9 (15): p. 3169.
9. Deng, J., W. Dong, R. Socher, L.-J. Li, K. Li, and L. Fei-Fei. Imagenet: A large-scale hierarchical image database. in 2009 IEEE conference on computer vision and pattern recognition. 2009. Ieee.
10. Cai, H., Z. Ao, C. Tian, Z. Wu, H. Liu, J. Tchieu, M. Gu, K. Mackie, and F. Guo, Brain organoid reservoir computing for artificial intelligence. Nature Electronics, 2023: p. 1-8.
11. Lukoševičius, M. and H. Jaeger, Reservoir computing approaches to recurrent neural network training. Computer science review, 2009. 3 (3): p. 127-149.
12. Pascanu, R., C. Gulcehre, K. Cho, and Y. Bengio, How to construct deep recurrent neural networks. arXiv preprint arXiv: 1312.6026, 2013.
13. Maass, W., T. Natschläger, and H. Markram, Real-time computing without stable states: A new framework for neural computation based on perturbations. Neural computation, 2002. 14 (11): p. 2531-2560.
14. Jaeger, H., The “echo state” approach to analysing and training recurrent neural networks-with an erratum note. Bonn, Germany: German National Research Center for Information Technology GMD Technical Report, 2001. 148 (34): p. 13.
15. Zhang, H. and D. V. Vargas, A survey on reservoir computing and its interdisciplinary applications beyond traditional machine learning. IEEE Access, 2023.
16. Sussillo, D. and L. F. Abbott, Generating coherent patterns of activity from chaotic neural networks. Neuron, 2009. 63 (4): p. 544-557.
17. Yada, Y., S. Yasuda, and H. Takahashi, Physical reservoir computing with FORCE learning in a living neuronal culture. Applied Physics Letters, 2021. 119 (17).
18. Franke, K., K. F. Willeke, K. Ponder, M. Galdamez, N. Zhou, T. Muhammad, S. Patel, E. Froudarakis, J. Reimer, and F. H. Sinz, State-dependent pupil dilation rapidly shifts visual feature selectivity. Nature, 2022. 610 (7930): p. 128-134.
19. Walker, E. Y., F. H. Sinz, E. Cobos, T. Muhammad, E. Froudarakis, P. G. Fahey, A. S. Ecker, J. Reimer, X. Pitkow, and A. S. Tolias, Inception loops discover what excites neurons most using deep predictive models. Nature neuroscience, 2019. 22 (12): p. 2060-2065.
20. Sinz, F., A. S. Ecker, P. Fahey, E. Walker, E. Cobos, E. Froudarakis, D. Yatsenko, Z. Pitkow, J. Reimer, and A. Tolias, Stimulus domain transfer in recurrent models for large scale cortical population prediction on video. Advances in neural information processing systems, 2018. 31.
21. Cadena, S. A., G. H. Denfield, E. Y. Walker, L. A. Gatys, A. S. Tolias, M. Bethge, and A. S. Ecker, Deep convolutional models improve predictions of macaque V1 responses to natural images. PLoS computational biology, 2019. 15 (4): p. e1006897.
22. Cadena, S. A., K. F. Willeke, K. Restivo, G. Denfield, F. H. Sinz, M. Bethge, A. S. Tolias, and A. S. Ecker, Diverse task-driven modeling of macaque V4 reveals functional specialization towards semantic tasks. bioRxiv, 2022.
23. Pierzchlewicz, P. A., K. F. Willeke, A. F. Nix, P. Elumalai, K. Restivo, T. Shinn, C. Nealley, G. Rodriguez, S. Patel, and K. Franke, Energy guided diffusion for generating neurally exciting images. bioRxiv, 2023.
24. Zeng, N., T. Jung, M. Sharma, G. Eichler, F. Fabbri, R. J. Cotton, E. Spinazzi, B. Youngerman, L. Carloni, and K. L. Shepard, A Wireless, Mechanically Flexible, 25 m-Thick, 65,536-Channel Subdural Surface Recording and Stimulating Microelectrode Array with Integrated Antennas, in Symposium on VLSI Circuit. 2023.
25. Shannon, R. V., A model of safe levels for electrical stimulation. IEEE Transactions on biomedical engineering, 1992. 39 (4): p. 424-426.
26. Yamins, D. L. and J. J. DiCarlo, Using goal-driven deep learning models to understand sensory cortex. Nature neuroscience, 2016. 19 (3): p. 356-365.
27. Trujillo, C. A., R. Gao, P. D. Negraes, J. Gu, J. Buchanan, S. Preissl, A. Wang, W. Wu, G. G. Haddad, and I. A. Chaim, Complex oscillatory waves emerging from cortical organoids model early human brain network development. Cell stem cell, 2019. 25 (4): p. 558-569. e7.
28. Yang, X., C. Forró, T. L. Li, Y. Miura, T. J. Zaluska, C.-T. Tsai, S. Kanton, J. P. McQueen, X. Chen, V. Mollo, F. Santoro, S. P. Pasca, and B. Cui, Kirigami electronics for long-term electrophysiological recording of human neural organoids and assembloids. Nature Biotechnology, 2024.
29. McDonald, M., D. Sebinger, L. Brauns, L. Gonzalez-Cano, Y. Menuchin-Lasowski, M. Mierzejewski, O.-E. Psathaki, A. Stumpf, J. Wickham, T. Rauen, H. Schöler, and P. D. Jones, A mesh microelectrode array for non-invasive electrophysiology within neural organoids. Biosensors and Bioelectronics, 2023. 228: p. 115223.
30. Stumpp, T., M. Mierzejewski, D. Pascual, A. Stumpf, and P. D. Jones, Scalable mesh microelectrode arrays for neural spheroids and organoids. Current Directions in Biomedical Engineering, 2023. 9 (1): p. 575-578.
31. Phouphetlinthong, O., E. Partiot, C. Bernou, A. Sebban, R. Gaudin, and B. Charlot, Protruding cantilever microelectrode array to monitor the inner electrical activity of cerebral organoids. Lab on a Chip, 2023. 23 (16): p. 3603-3614.
32. Yoon, D. Y., S. Pinto, S. Chung, P. Merolla, T. W. Koh, and D. Seo. A 1024-Channel Simultaneous Recording Neural SoC with Stimulation and Real-Time Spike Detection. in 2021 Symposium on VLSI Circuits. 2021.
33. Lancaster, M. A., M. Renner, C.-A. Martin, D. Wenzel, L. S. Bicknell, M. E. Hurles, T. Homfray, J. M. Penninger, A. P. Jackson, and J. A. Knoblich, Cerebral organoids model human brain development and microcephaly. Nature, 2013. 501 (7467): p. 373-379.
34. Buzsáki, G., C. A. Anastassiou, and C. Koch, The origin of extracellular fields and currents—EEG, ECOG, LFP and spikes. Nat Rev Neurosci, 2012. 13 (6): p. 407-420.
35. Christie, B. P., D. M. Tat, Z. T. Irwin, V. Gilja, P. Nuyujukian, J. D. Foster, S. I. Ryu, K. V. Shenoy, D. E. Thompson, and C. A. Chestek, Comparison of spike sorting and thresholding of voltage waveforms for intracortical brain-machine interface performance. Journal of neural engineering, 2014. 12 (1): p. 016009.
36. Wagenaar, D. A., J. Pine, and S. M. Potter, Effective parameters for stimulation of dissociated cultures using multi-electrode arrays. Journal of Neuroscience Methods, 2004. 138 (1): p. 27-37.
37. Hasani, R., M. Lechner, A. Amini, D. Rus, and R. Grosu. Liquid time-constant networks. in Proceedings of the AAAI Conference on Artificial Intelligence. 2021.
38. Chahine, M., R. Hasani, P. Kao, A. Ray, R. Shubert, M. Lechner, A. Amini, and D. Rus, Robust flight navigation out of distribution with liquid neural networks. Science Robotics, 2023. 8 (77): p. eadc8892.
39. Wang, E. Y., P. G. Fahey, K. Ponder, Z. Ding, A. Chang, T. Muhammad, S. Patel, Z. Ding, D. Tran, J. Fu, S. Papadopoulos, K. Franke, A. S. Ecker, J. Reimer, X. Pitkow, F. H. Sinz, and A. S. Tolias, Towards a Foundation Model of the Mouse Visual Cortex. bioRxiv, 2023.
40. Lechner, M., R. Hasani, M. Zimmer, T. A. Henzinger, and R. Grosu. Designing worm-inspired neural networks for interpretable robotic control. in 2019 International Conference on Robotics and Automation (ICRA). 2019. IEEE.
41. Wicks, S. R., C. J. Roehrig, and C. H. Rankin, A dynamic network simulation of the nematode tap withdrawal circuit: predictions concerning synaptic function using behavioral criteria. Journal of Neuroscience, 1996. 16 (12): p. 4017-4031.
42. Ho, J., N. Kalchbrenner, D. Weissenborn, and T. Salimans, Axial attention in multidimensional transformers. arXiv preprint arXiv: 1912.12180, 2019.
43. Arnab, A., M. Dehghani, G. Heigold, C. Sun, M. Lučić, and C. Schmid. Vivit: A video vision transformer. in Proceedings of the IEEE/CVF international conference on computer vision. 2021.
44. Nayakanti, N., R. Al-Rfou, A. Zhou, K. Goel, K. S. Refaat, and B. Sapp. Wayformer: Motion forecasting via simple & efficient attention networks. in 2023 IEEE International Conference on Robotics and Automation (ICRA). 2023. IEEE.
45. Su, J., M. Ahmed, Y. Lu, S. Pan, W. Bo, and Y. Liu, Roformer: Enhanced transformer with rotary position embedding. Neurocomputing, 2024. 568: p. 127063.
46. Lukoševičius, M., A practical guide to applying echo state networks, in Neural Networks: Tricks of the Trade: Second Edition. 2012, Springer. p. 659-686.
47 Tjitse van der Molen, T., A. Spaeth, M. Chini, J. Bartram, A. Dendukuri, Z. Zhang, K. Bhaskaran-Nair, L. J. Blauvelt, L. R. Petzold, and P. K. Hansma, Protosequences in human cortical organoids model intrinsic states in the developing cortex. bioRxiv, 2023: p. 2023.12. 29.573646.
48. Morris, J. X., W. Zhao, J. T. Chiu, V. Shmatikov, and A. M. Rush, Language Model Inversion. arXiv preprint arXiv: 2311.13647, 2023.
49. Lowenthal, J., S. Lipnick, M. Rao, and S. C. Hull, Specimen collection for induced pluripotent stem cell research: harmonizing the approach to informed consent. Stem Cells Transl Med, 2012. 1 (5): p. 409-21.
50. Koplin, J. J. and J. Savulescu, Moral limits of brain organoid research. The Journal of Law, Medicine & Ethics, 2019. 47 (4): p. 760-767.
51. Hyun, I., J. Scharf-Deering, and J. E. Lunshof, Ethical issues related to brain organoid research. Brain research, 2020. 1732: p. 146653.
52. Klitzman, R., E. Pivovarova, and C. W. Lidz, Single IRBs in multisite trials: questions posed by the new NIH policy. Jama, 2017. 317 (20): p. 2061-2062.
53. Lidz, C. W., E. Pivovarova, P. Appelbaum, D. F. Stiles, A. Murray, and R. L. Klitzman, Reliance agreements and single IRB review of multisite research: Concerns of IRB members and staff. AJOB Empirical Bioethics, 2018. 9 (3): p. 164-172.
54. Diamond, M. P., E. Eisenberg, H. Huang, C. Coutifaris, R. S. Legro, K. R. Hansen, A. Z. Steiner, M. Cedars, K. Barnhart, and T. Ziolek, The efficiency of single institutional review board review in National Institute of Child Health and Human Development Cooperative Reproductive Medicine Network—initiated clinical trials. Clinical Trials, 2019. 16 (1): p. 3-10.
55. Klitzman, R., E. Pivovarova, A. Murray, P. S. Appelbaum, D. F. Stiles, and C. W. Lidz, Local knowledge and single IRBs for multisite studies: challenges and solutions. Ethics & Human Research, 2019. 41 (1): p. 22-31.
56. Klitzman, R., P. S. Appelbaum, A. Murray, E. Pivovarova, D. F. Stiles, and C. W. Lidz, When IRBs say no to participating in research about single IRBs. Ethics & human research, 2020. 42 (1): p. 36-40.
57. Murray, A., E. Pivovarova, R. Klitzman, D. F. Stiles, P. Appelbaum, and C. W. Lidz, Reducing the single IRB burden: streamlining electronic IRB systems. AJOB empirical bioethics, 2021. 12 (1): p. 33-40.
58. Klitzman, R., How local IRBs view central IRBs in the US. BMC Medical Ethics, 2011. 12 (1): p. 1-14.
59. Klitzman, R., How IRB leaders view and approach challenges raised by industry-funded research. IRB, 2013. 35 (3): p. 9.
60. Klitzman, R., How good does the science have to be in proposals submitted to institutional review boards? An interview study of institutional review board personnel. Clinical trials, 2013. 10 (5): p. 761-766.
61. Klitzman, R. L., How IRBs view and make decisions about social risks. Journal of Empirical Research on Human Research Ethics, 2013. 8 (3): p. 58-65.
62. Klitzman, R., “Members of the same club”: Challenges and decisions faced by US IRBs in identifying and managing conflicts of interest. PLoS One, 2011. 6 (7): p. e22796.
63. Klitzman, R., Views and experiences of IRBs concerning research integrity. The Journal of Law, Medicine & Ethics, 2011. 39 (3): p. 513-528.
64. Klitzman, R., From anonymity to “open doors”: IRB responses to tensions with researchers. BMC research notes, 2012. 5: p. 1-11.
65. Klitzman, R. and M. V. Sauer, Payment of egg donors in stem cell research in the USA. Reproductive biomedicine online, 2009. 18 (5): p. 603-608.
66. Klitzman, R. and M. V. Sauer, Creating and selling embryos for “donation”: ethical challenges. American journal of obstetrics and gynecology, 2015. 212 (2): p. 167-170. el.
67. Keyes, R. W. and R. Landauer, Minimal energy dissipation in logic. IBM Journal of Research and Development, 1970. 14 (2): p. 152-157.
68. Diamantini, M. C., L. Gammaitoni, and C. A. Trugenberger, Landauer bound for analog computing systems. Physical Review E, 2016. 94 (1): p. 012139.
69. Lin, C. K., A. Wild, G. N. Chinya, Y. Cao, M. Davies, D. M. Lavery, and H. Wang, Programming Spiking Neural Networks on Intel's Loihi. Computer, 2018. 51 (3): p. 52-61.
70. Zheng, H., Y. Wu, L. Deng, Y. Hu, and G. Li. Going deeper with directly-trained larger spiking neural networks. in Proceedings of the AAAI conference on artificial intelligence. 2021.
71. Li, Y., Y. Guo, S. Zhang, S. Deng, Y. Hai, and S. Gu, Differentiable spike: Rethinking gradient-descent for training spiking neural networks. Advances in Neural Information Processing Systems, 2021. 34: p. 23426-23439.
72. Fang, W., Z. Yu, Y. Chen, T. Huang, T. Masquelier, and Y. Tian, Deep residual learning in spiking neural networks. Advances in Neural Information Processing Systems, 2021. 34: p. 21056-21069.
73. Deng, S., Y. Li, S. Zhang, and S. Gu, Temporal efficient training of spiking neural network via gradient re-weighting. arXiv preprint arXiv: 2202.11946, 2022.
74. Werbos, P. J., Backpropagation through time: what it does and how to do it. Proceedings of the IEEE, 1990. 78 (10): p. 1550-1560.
75. Shrestha, S. B. and G. Orchard, Slayer: Spike layer error reassignment in time. Advances in neural information processing systems, 2018. 31.
76. Wu, Y., L. Deng, G. Li, J. Zhu, and L. Shi, Spatio-temporal backpropagation for training high-performance spiking neural networks. Frontiers in neuroscience, 2018. 12: p. 331.
77. Bellec, G., D. Salaj, A. Subramoney, R. Legenstein, and W. Maass, Long short-term memory and learning-to-learn in networks of spiking neurons. Advances in neural information processing systems, 2018. 31.
78. Jin, Y., W. Zhang, and P. Li, Hybrid macro/micro level backpropagation for training deep spiking neural networks. Advances in neural information processing systems, 2018.
79. Wu, Y., L. Deng, G. Li, J. Zhu, Y. Xie, and L. Shi. Direct training for spiking neural networks: Faster, larger, better. in Proceedings of the AAAI conference on artificial intelligence. 2019.
80. Neftci, E. O., H. Mostafa, and F. Zenke, Surrogate gradient learning in spiking neural networks: Bringing the power of gradient-based optimization to spiking neural networks. IEEE Signal Processing Magazine, 2019. 36 (6): p. 51-63.
81. Kim, J., K. Kim, and J.-J. Kim, Unifying activation-and timing-based learning rules for spiking neural networks. Advances in neural information processing systems, 2020. 33: p. 19534-19544.
82. Fang, W., Z. Yu, Y. Chen, T. Masquelier, T. Huang, and Y. Tian. Incorporating learnable membrane time constant to enhance learning of spiking neural networks. in Proceedings of the IEEE/CVF international conference on computer vision. 2021.
83. Shekar, S., K. Jayant, M. Rabadan, R. Tomer, R. Yuste, and K. L. Shepard, A miniaturized multi-clamp CMOS amplifier for intracellular neural recording. Nature electronics, 2019. 2 (8): p. 343-350.
84. Taal, A. J., I. Uguz, S. Hillebrandt, C.-K. Moon, V. Andino-Pavlovsky, J. Choi, C. Keum, K. Deisseroth, M. C. Gather, and K. L. Shepard, Single-neuron-resolution optogenetic stimulation in the deep brain with a CMOS probe containing 1024 monolithically integrated organic LED pixels. Nature Electronics, 2023
85. Tsai, D., D. Sawyer, A. Bradd, R. Yuste, and K. L. Shepard, A very large-scale microelectrode array for cellular-resolution electrophysiology. Nature communications, 2017.8 (1): p. 1802.
86. Choi, J., A. J. Taal, E. H. Pollmann, C. Lee, K. Kim, L. C. Moreaux, M. L. Roukes, and K. L. Shepard, A 512-Pixel, 51-kHz-Frame-Rate, Dual-Shank, Lens-Less, Filter-Less Single-Photon Avalanche Diode CMOS Neural Imaging Probe. IEEE Journal of Solid-State Circuits, 2019. 54 (11): p. 2957-2968.
87. Choi, J., A. J. Taal, E. H. Pollmann, W. Meng, S. Moazeni, L. C. Moreaux, M. L. Roukes, and K. L. Shepard. Fully Integrated Time-Gated 3D Fluorescence Imager for Deep Neural Imaging. in 2019 IEEE Biomedical Circuits and Systems Conference (BioCAS). 2019. IEEE.
88. Lee, C., A. J. Taal, J. Choi, K. Kim, K. Tien, L. Moreaux, M. L. Roukes, and K. L. Shepard. 11.5 A 512-Pixel 3 kHz-frame-rate dual-shank lensless filterless single-photon-avalanche-diode CMOS neural imaging probe. in 2019 IEEE International Solid-State Circuits Conference-(ISSCC). 2019. IEEE.
89. Hillebrandt, S., C. K. Moon, A. J. Taal, H. Overhauser, K. L. Shepard, and M. C. Gather, High-Density Integration of Ultrabright OLEDs on a Miniaturized Needle-Shaped CMOS Backplane. Advanced Materials, 2023: p. 2300578.
90. Pollmann, E. H., H. Yin, I. Uguz, A. Dubey, K. E. Wingel, J. S. Choi, S. Moazeni, Y. Gilhotra, V. A. Pavlovsky, A. Banees, V. Boominathan, J. Robinson, A. Veeraraghavan, V. A. Pieribone, B. Pesaran, and K. L. Shepard, Subdural CMOS optical probe (SCOPe) for bidirectional neural interfacing. bioRxiv, 2023: p. 2023.02.07.527500.
91. Taal, A. J., C. Lee, J. Choi, B. Hellenkamp, and K. L. Shepard, Toward implantable devices for angle-sensitive, lens-less, multifluorescent, single-photon lifetime imaging in the brain using Fabry-Perot and absorptive color filters. Light: Science & Applications, 2022. 11 (1): p. 1-15.
92. Moazeni, S., E. H. Pollmann, V. Boominathan, F. A. Cardoso, J. T. Robinson, A. Veeraraghavan, and K. Shepard, A Mechanically Flexible, Implantable Neural Interface for Computational Imaging and Optogenetic Stimulation over 5.45. 4 mm 2 FoV. IEEE Transactions on Biomedical Circuits and Systems, 2021.
93. Moazeni, S., E. H. Pollmann, V. Boominathan, F. A. Cardoso, J. T. Robinson, A. Veeraraghavan, and K. L. Shepard. A Mechanically Flexible Implantable Neural Interface for Computational Imaging and Optogenetic Stimulation over 5.4×5.4 mm 2 FoV. in 2021 IEEE International Solid-State Circuits Conference (ISSCC). 2021. IEEE.
94. Gilhotra, Y., H. Overhauser, H. Yin, E. Pollmann, G. Eichler, A. Cheng, T. Jung, N. Zeng, L. Carloni, and K. Shepard. A Wireless Subdural Optical Cortical Interface Device with 768 Co-Packaged Micro-LEDs for Fluorescence Imaging and Optogenetic Stimulation, in IEEE Custom Integrated Circuits Conference. 2024.
95. Moreaux, L. C., D. Yatsenko, W. D. Sacher, J. Choi, C. Lee, N. J. Kubat, R. J. Cotton, E. S. Boyden, M. Z. Lin, L. Tian, A. S. Tolias, J. Poon, K. L. Shepard, and M. L. Roukes, Integrated neurophotonics: toward dense volumetric interrogation of brain circuit activity—at depth and in real time. Neuron, 2020. 108 (1): p. 66-92.
96. Baker, C., E. Froudarakis, D. Yatsenko, A. S. Tolias, and R. Rosenbaum, Inference of synaptic connectivity and external variability in neural microcircuits. Journal of computational neuroscience, 2020. 48: p. 123-147.
97. Froudarakis, E., U. Cohen, M. Diamantaki, E. Y. Walker, J. Reimer, P. Berens, H. Sompolinsky, and A. S. Tolias, Object manifold geometry across the mouse cortical visual hierarchy. BioRxiv, 2020: p. 2020.08. 20.258798.
98. Froudarakis, E., P. G. Fahey, J. Reimer, S. M. Smirnakis, E. J. Tehovnik, and A. S. Tolias, The visual cortex in context. Annual review of vision science, 2019. 5: p. 317-339.
99. Sinz, F. H., X. Pitkow, J. Reimer, M. Bethge, and A. S. Tolias, Engineering a less artificial intelligence. Neuron, 2019. 103 (6): p. 967-979.
100. Yang, Q., E. Walker, R. J. Cotton, A. S. Tolias, and X. Pitkow, Revealing nonlinear neural decoding by analyzing choices. Nature communications, 2021. 12 (1): p. 6557.
101. Willeke, K. F., K. Restivo, K. Franke, A. F. Nix, S. A. Cadena, T. Shinn, C. Nealley, G. Rodriguez, S. Patel, and A. S. Ecker, Deep learning-driven characterization of single cell tuning in primate visual area V4 unveils topological organization. bioRxiv, 2023: p. 2023.05. 12.540591.
102. Cadena, S. A., K. F. Willeke, K. Restivo, G. Denfield, F. H. Sinz, M. Bethge, A. S. Tolias, and A. S. Ecker, Diverse task-driven modeling of macaque V4 reveals functional specialization towards semantic tasks. bioRxiv, 2022: p. 2022.05. 18.492503.
103. Patounakis, G., K. L. Shepard, and R. Revicky, Active CMOS array sensor for time-resolved fluorescence detection. IEEE Journal of Solid-State Circuits, 2006. 41 (11): p. 2521-2530.
104. Levine, P. M., P. Gong, R. Levicky, and K. L. Shepard, Real-time, multiplexed electrochemical DNA detection using an active complementary metal-oxide-semiconductor biosensor array with integrated sensor electronics. Biosensors and Bioelectronics, 2009. 24 (7): p. 1995-2001.
105. Levine, P. M., G. Ping, R. Levicky, and K. L. Shepard, Active CMOS Sensor Array for Electrochemical Biomolecular Detection. Solid-State Circuits, IEEE Journal of, 2008. 43 (8): p. 1859-1871.
106. Huang, T. C. D., S. Sorgenfrei, P. Gong, R. Levicky, and K. L. Shepard, A 0.18-mu m CMOS Array Sensor for Integrated Time-Resolved Fluorescence Detection. IEEE Journal of Solid-State Circuits, 2009. 44 (5): p. 1644-54.
107. Rosenstein, J. K., M. Wanunu, C. A. Merchant, M. Drndic, and K. L. Shepard, Integrated nanopore sensing platform with sub-microsecond temporal resolution. Nat Meth, 2012. 9 (5): p. 487-492.
108. Sorgenfrei, S., C.-y. Chiu, M. Johnston, C. Nuckolls, and K. L. Shepard, Debye Screening in Single-Molecule Carbon Nanotube Field-Effect Sensors. Nano Letters, 2011. 11 (9): p. 3739-3743.
109. Sorgenfrei, S., C. Y. Chiu, R. L. Gonzalez, Y. J. Yu, P. Kim, C. Nuckolls, and K. L. Shepard, Label-free single-molecule detection of DNA-hybridization kinetics with a carbon nanotube field-effect transistor. Nature Nanotechnology, 2011. 6 (2): p. 125-131.
110. Meric, I., N. Baklitskaya, P. Kim, and K. L. Shepard. RF performance of top-gated, zero-bandgap graphene field-effect transistors. in Electron Devices Meeting, 2008. IEDM 2008. IEEE International. 2008. San Francisco, CA, USA.
111. Meric, I., C. R. Dean, A. F. Young, N. Baklitskaya, N. J. Tremblay, C. Nuckolls, P. Kim, and K. L. Shepard, Channel Length Scaling in Graphene Field-Effect Transistors Studied with Pulsed Current-Voltage Measurements. Nano Letters, 2011. 11 (3): p. 1093-1097.
112. Meric, I., M. Y. Han, A. F. Young, B. Ozyilmaz, P. Kim, and K. L. Shepard, Current saturation in zero-bandgap, top-gated graphene field-effect transistors. Nat Nano, 2008. 3 (11): p. 654-659.
113. Dean, C. R., A. F. Young, I. Meric, C. Lee, L. Wang, S. Sorgenfrei, K. Watanabe, T. Taniguchi, P. Kim, and K. L. Shepard, Boron nitride substrates for high-quality graphene electronics. Nature nanotechnology, 2010. 5 (10): p. 722.
114. Sturcken, N., R. Davies, C. Cheng, W. E. Bailey, and K. L. Shepard. Design of coupled power inductors with crossed anisotropy magnetic core for integrated power conversion. in Applied Power Electronics Conference and Exposition (APEC), 2012 Twenty-Seventh Annual IEEE. 2012.
115. Sturcken, N., R. Davies, H. C. Wu, M. Lekas, M. Arienzo, K. Shepard, K. W. Cheng, C. C. Chen, Y. S. Su, C. Y. Tsai, K. D. Wu, J. Y. Wu, Y. C. Wang, K. C. Liu, C. C. Hsu, C. L. Chang, W. C. Hua, and A. Kalnitsky. Magnetic thin-film inductors for monolithic integration with CMOS. in Proceedings of the International Electron Devices Meeting. 2015.
116. Sturcken, N., E. J. O'Sullivan, N. Wang, P. Herget, B. C. Webb, L. T. Romankiw, M. Petracca, R. Davies, R. E. Fontana, G. M. Decad, I. Kymissis, A. V. Peterchev, L. P. Carloni, W. J. Gallagher, and K. L. Shepard, A 2.5D Integrated Voltage Regulator Using Coupled-Magnetic-Core Inductors on Silicon Interposer. Solid-State Circuits, IEEE Journal of, 2013. 48 (1): p. 244-254.
117. Sturcken, N., M. Petracca, S. Warren, P. Mantovani, L. P. Carloni, A. V. Peterchev, and K. L. Shepard, A Switched-Inductor Integrated Voltage Regulator With Nonlinear Feedback and Network-on-Chip Load in 45 nm SOI. Solid-State Circuits, IEEE Journal of, 2012. 47 (8): p. 1935-1945.
118. Field, R. M., J. Lary, J. Cohn, L. Paninski, and K. L. Shepard, A low-noise, single-photon avalanche diode in standard 0.13 μm complementary metal-oxide-semiconductor process. Applied Physics Letters, 2010. 97 (21): p. 211111-211111.
119. Field, R. M., S. Realov, and K. L. Shepard, A 100 fps, time-correlated single-photon-counting-based fluorescence-lifetime imager in 130 nm CMOS. IEEE Journal of Solid-State Circuits, 2014. 49 (4): p. 867-880.
120. Tambe, T., J. Zhang, C. Hooper, T. Jia, P. N. Whatmough, J. Zuckerman, M. C. Dos Santos, E. J. Loscalzo, D. Giri, and K. Shepard. 22.9 A 12 nm 18.1 TFLOPs/W Sparse Transformer Processor with Entropy-Based Early Exit, Mixed-Precision Predication and Fine-Grained Power Management. in 2023 IEEE International Solid-State Circuits Conference (ISSCC). 2023. IEEE.
121. Santos, M. C.d., T. Jia, M. Cochet, K. Swaminathan, J. Zuckerman, P. Mantovani, D. Giri, J. J. Zhang, E. J. Loscalzo, and G. Tombesi. A Scalable Methodology for Agile Chip Development with Open-Source Hardware Components. in Proceedings of the 41st IEEE/ACM International Conference on Computer-Aided Design. 2022.
122. Jia, T., P. Mantovani, M. C. Dos Santos, D. Giri, J. Zuckerman, E. J. Loscalzo, M. Cochet, K. Swaminathan, G. Tombesi, and J. J. Zhang. A 12 nm Agile-Designed SoC for Swarm-Based Perception with Heterogeneous IP Blocks, a Reconfigurable Memory Hierarchy, and an 800 MHz Multi-Plane NoC. in ESSCIRC 2022-IEEE 48th European Solid State Circuits Conference (ESSCIRC). 2022. IEEE.
123. Froudarakis, E., P. Berens, A. S. Ecker, R. J. Cotton, F. H. Sinz, D. Yatsenko, P. Saggau, M. Bethge, and A. S. Tolias, Population code in mouse V1 facilitates readout of natural scenes through increased sparseness. Nature neuroscience, 2014. 17 (6): p. 851-857.
124. Denfield, G. H., A. S. Ecker, T. J. Shinn, M. Bethge, and A. S. Tolias, Attentional fluctuations induce shared variability in macaque primary visual cortex. Nature communications, 2018. 9 (1): p. 1-14.
125. Tolias, A. S., A. S. Ecker, A. G. Siapas, A. Hoenselaar, G. A. Keliris, and N. K. Logothetis, Recording chronically from the same neurons in awake, behaving primates. Journal of neurophysiology, 2007. 98 (6): p. 3780-3790.
126. Fahey, P. G., T. Muhammad, C. Smith, E. Froudarakis, E. Cobos, J. Fu, E. Y. Walker, D. Yatsenko, F. H. Sinz, and J. Reimer, A global map of orientation tuning in mouse visual cortex. BioRXiv, 2019: p. 745323.
127. Karzbrun, E., A. H. Khankhel, H. C. Megale, S. M. Glasauer, Y. Wyle, G. Britton, A. Warmflash, K. S. Kosik, E. D. Siggia, and B. I. Shraiman, Human neural tube morphogenesis in vitro by geometric constraints. Nature, 2021. 599 (7884): p. 268-272.
128. Han, D., G. Liu, Y. Oh, S. Oh, S. Yang, L. Mandjikian, N. Rani, M. C. Almeida, K. S. Kosik, and J. Jang, ZBTB12 is a molecular barrier to dedifferentiation in human pluripotent stem cells. Nature Communications, 2023. 14 (1): p. 632.
129. Jang, J., D. Han, M. Golkaram, M. Audouard, G. Liu, D. Bridges, S. Hellander, A. Chialastri, S. S. Dey, and L. R. Petzold, Control over single-cell distribution of G1 lengths by WNT governs pluripotency. PLoS biology, 2019. 17 (9): p. e3000453.
130. Jang, J., Y. Wang, H.-S. Kim, M. A. Lalli, and K. S. Kosik, Nrf2, a regulator of the proteasome, controls self-renewal and pluripotency in human embryonic stem cells. Stem cells, 2014. 32 (10): p. 2616-2625.
131. Xu, N., T. Papagiannakopoulos, G. Pan, J. A. Thomson, and K. S. Kosik, MicroRNA-145 regulates OCT4, SOX2, and KLF4 and represses pluripotency in human embryonic stem cells. Cell, 2009. 137 (4): p. 647-658.
132. Glasauer, S. M., S. K. Goderie, J. N. Rauch, E. Guzman, M. Audouard, T. Bertucci, S. Joy, E. Rommelfanger, G. Luna, and E. Keane-Rivera, Human tau mutations in cerebral organoids induce a progressive dyshomeostasis of cholesterol. Stem cell reports, 2022. 17 (9): p. 2127-2140.
133. Rani, N., T. J. Nowakowski, H. Zhou, S. E. Godshalk, V. Lisi, A. R. Kriegstein, and K. S. Kosik, A primate lncRNA mediates notch signaling during neuronal development by sequestering miRNA. Neuron, 2016. 90 (6): p. 1174-1188.
134. Wen, Z., H. N. Nguyen, Z. Guo, M. A. Lalli, X. Wang, Y. Su, N.-S. Kim, K.-J. Yoon, J. Shin, and C. Zhang, Synaptic dysregulation in a human iPS cell model of mental disorders. Nature, 2014. 515 (7527): p. 414-418.
135. Klitzman, R. The use of eggs and embryos in stem cell research. in Seminars in reproductive medicine. 2010. @ Thieme Medical Publishers.
136. Klitzman, R. L. and M. V. Sauer, Kamakahi vs ASRM and the future of compensation for human eggs. American journal of obstetrics and gynecology, 2015. 213 (2): p. 186-187. e1.
137. Klitzman, R., Buying and selling human eggs: infertility providers' ethical and other concerns regarding egg donor agencies. BMC medical ethics, 2016. 17 (1): p. 1-10.
138. Klitzman, R., W. Chung, K. Marder, A. Shanmugham, L. J. Chin, M. Stark, C.-S. Leu, and P. S. Appelbaum, Views of internists towards uses of PGD. Reproductive biomedicine online, 2013. 26 (2): p. 142-147.
139. Klitzman, R., Henrietta Lacks' family's lawsuits: ethical questions and solutions. Trends in Biotechnology, 2022. 40 (7): p. 769-772.
140. Klitzman, R. L., Misunderstandings concerning genetics among patients confronting genetic disease. Journal of genetic counseling, 2010. 19: p. 430-446.
141. Klitzman, R., Exclusion of genetic information from the medical record: ethical and medical dilemmas. Jama, 2010. 304 (10): p. 1120-1121.
142. Klitzman, R. and W. Chung, The process of deciding about prophylactic surgery for breast and ovarian cancer: Patient questions, uncertainties, and communication. American Journal of Medical Genetics Part A, 2010. 152 (1): p. 52-66.
143. Klitzman, R., “Am I my genes?”: Questions of identity among individuals confronting genetic disease. Genetics in Medicine, 2009. 11 (12): p. 880-889.
144. Klitzman, R., Views of discrimination among individuals confronting genetic disease. Journal of Genetic Counseling, 2010. 19: p. 68-83.
145 Sugarman, J., D. M. Wenner, A. Rid, L. M. Henry, F. Luna, R. Klitzman, K. M. MacQueen, S. Rennie, J. A. Singh, and L. O. Gostin, Ethical research when abortion access is legally restricted. Science, 2023. 380 (6651): p. 1224-1226.
146. Klitzman, R., The ethics police?: The struggle to make human research safe. 2015: Oxford University Press.
147. Klitzman, R. L., How IRBs View and Make Decisions about Consent Forms. Journal of Empirical Research on Human Research Ethics, 2013. 8 (1): p. 8-19.
148. Appelbaum, P. S., C. R. Waldman, A. Fyer, R. Klitzman, E. Parens, J. Martinez, W. N. Price II, and W. K. Chung, Informed consent for return of incidental findings in genomic research. Genetics in Medicine, 2014. 16 (5): p. 367-373.
149. Klitzman, R., How US institutional review boards decide when researchers need to translate studies. Journal of medical ethics, 2013.
150. Klitzman, R., Consenting for molecular diagnostics. Clinical chemistry, 2015. 61 (1): p. 139-141.
151. Klitzman, R., L. J. Chin, H. Rifai-Bishjawish, K. Kleinert, and C.-S. Leu, Disclosures of funding sources and conflicts of interest in published HIV/AIDS research conducted in developing countries. Journal of Medical Ethics, 2010. 36 (8): p. 505.
152. Powell, K., R. Terry, and S. Chen, How LGBT+ scientists would like to be included and welcomed in STEM workplaces. Nature (London), 2020. 586: p. 813-816.
153. Gibney, E., Discrimination drives LGBT+ scientists to think about quitting. Nature, 2019. 571 (7763): p. 16-18.

What is claimed is:

1. A brain-organoid complementary metal-oxide semiconductor (CMOS) processor, comprising:
at least one culture including:
at least one brain organoid, and
at least one CMOS device configured to interface with the at least one brain organoid,
wherein the at least one CMOS device is configured to stimulate and record information from the at least one brain organoid.

2. The processor according to claim 1, wherein the at least one CMOS device is configured to electro-physiologically interface with the at least one brain organoid.

3. The processor according to claim 1, wherein the at least one CMOS device is configured to optically interface with the at least one brain organoid.

4. The processor according to claim 1, wherein the at least one CMOS device is configured to perform at least one operation or at least one computation to interface with the at least one brain organoid.

5. The processor according to claim 4, wherein the at least one operation includes a performance of (i) encoding and decoding spikes from the at least one brain organoid, and (ii) input or output layer training.

6. The processor according to claim 1, wherein the at least one CMOS device includes one or more wireless interfaces.

7. The processor according to claim 1, wherein the at least one brain organoid is configured to operate as a reservoir in a reservoir computing model.

8. The processor according to claim 1, wherein the at least one brain organoid has at least one of learning structure or a long-term memory which is utilized in a computing model.

9. The processor according to claim 1, wherein the at least one CMOS device is thinned.

10. The processor according to claim 1, wherein the at least one CMOS device has one or more holes etched therethrough.

11. The process according to claim 1, wherein the at least one CMOS device is a plurality of CMOS devices, at least two of which are mounted in a back-to-back or stacked configuration with respect to one another.

12. The processor according to claim 1, wherein the one or more brain organoids acts a co-processor.

13. The processor according to claim 1, wherein the at least one CMOS device includes at least one feedback back loop connected to the at least one brain organoid.

14. The processor according to claim 1, wherein the at least one CMOS device includes a plurality of CMOS devices which are provided in a three-dimensional configuration.

15. The processor according to claim 1, wherein the at least one CMOS device includes a plurality of CMOS devices which are provided in a stacked configuration.

16. The processor according to claim 1, further comprising at least one interface providing a wireless connection, wherein the at least one interface is coupled to the at least one CMOS device.

17. A method for utilizing a brain-organoid complementary metal-oxide semiconductor (CMOS) structure, comprising:
providing at least one culture which includes:
at least one brain organoid, and
at least one CMOS device configured to interface with the at least one brain organoid; and
stimulating and recording information from the at least one brain organoid using the at least one CMOS device.

18. The method according to claim 17, further comprising electro-physiologically interfacing the CMOS device with the at least one brain organoid.

19. The method according to claim 17, further comprising optically interfacing the CMOS device with the at least one brain organoid.

20. The method according to claim 17, further comprising causing the at least one CMOS device to perform at least one operation or at least one computation to interface with the at least one brain organoid.

21. The method according to claim 20, wherein the at least one operation includes a performance of (i) encoding and decoding spikes from the at least one brain organoid, and (ii) input or output layer training.

22. The method according to claim 20, wherein the at least one CMOS device includes at least one feedback back loop connected to the at least one brain organoid.

23. The method according to claim 17, wherein the at least one CMOS device includes a plurality of CMOS devices which are provided in a three-dimensional configuration.

24. The method according to claim 17, wherein the at least one CMOS device includes a plurality of CMOS devices which are provided in a stacked configuration.

25. The method according to claim 17, further comprising providing a wireless connection using at least one interface which is coupled to the at least one CMOS device.
